(19) United States
(12) Patent Application Publication
(10) Pub. No.: US 2007/0200185 A1
(43) Pub. Date: Aug. 30, 2007

(54) Semiconductor device and method for fabricating the same

(76) Inventors: Junji Hirase, Osaka (JP); Naoki Kotani, Hyogo (JP); Shinji Takeoka, Osaka (JP); Gen Okazaki, Hyogo (JP); Akio Sebe, Osaka (JP); Kazuhiko Aida, Chiba (JP)

Correspondence Address: MCDERMOTT WILL & EMERY LLP, 600 13TH STREET, N.W., WASHINGTON, DC, 20005-3096, US

(21) Appl. No.: 11/543,865

(22) Filed: Oct. 6, 2006

(30) Foreign Application Priority Data
Feb. 27, 2006 (JP) 2006-050158

(51) Int. Cl. H01L 29/94

(52) U.S. Cl. 257/410

(57) ABSTRACT

A high dielectric constant gate insulating film is formed on an active region of a substrate, and a gate electrode is formed on the high dielectric constant gate insulating film. A high dielectric constant insulating sidewall is formed on a side face of the gate electrode.

### BACKGROUND of THE INVENTION

The present invention relates to a semiconductor device and a method for fabricating the same, and more particularly, it specifically relates to a structure of and a method for fabricating a MISFET (metal insulator semiconductor field effect transistor) and mainly relates to a technique to improve the driving power and the reliability of a MISFET.

Recently, in accordance with the increased degree of integration, the improved performance and the increased speed of semiconductor integrated circuit devices, the junction depth of an extension has been reduced in accordance with a scaling law, and a high dielectric constant film with a dielectric constant of approximately 10 or more, such as a Hf-based oxide film or an Al-based oxide film, has become to be used as a gate insulating film of a MISFET instead of a SiO₂-based insulating film with a dielectric constant of approximately 4.

FIGS. 31A and 31B are cross-sectional views for showing the structures of MISFETs using conventional high dielectric constant gate insulating films (see, for example, Non-patent document 1 below).

As shown in FIG. 31A, a gate electrode 105 is formed above a portion, surrounded with an STI (shallow trench isolation) 103, of a well 102 corresponding to an active region of a substrate 101 with a high dielectric constant gate insulating film 104 sandwiched therebetween. An insulating sidewall 107 is formed on the side face of the gate electrode 105. An extension region 110 is formed in a portion of the well 102 disposed below the sidewall 107, and a pocket region 111 is formed in a portion of the well 102 disposed below the extension region 110. A source/drain region 112 is formed in a portion of the well 102 disposed away from the gate electrode 105 beyond the extraction region 110 and the pocket region 111.

The structure of FIG. 31B is different from that of FIG. 31A in an insulating offset sidewall 106 provided between the side face of the gate electrode 105 and the sidewall 107. As a result, the overlap between the gate electrode 105 and the extension region 10 can be easily optimized.

Non-patent document 1: Ken Watanabe, “HfSiON-CMOS technology for achieving high performance and high reliability”, Semi. Forum Japan 2005

Non-patent document 2: T. Hori, IEDM Tech. Dig., 1989, p. 777

Non-patent document 3: H. Sayama et al., IEDM Tech. Dig. 2000, p. 239

### SUMMARY of THE INVENTION

In the structure of a MISFET using such a conventional high dielectric constant gate insulating film, however, since a side end portion of the high dielectric constant gate insulating film is in direct contact with the sidewall made of, for example, a silicon oxide film, there arises a problem, for example, that the composition of the side end portion of the high dielectric constant gate insulating film approximates to SiO₂ during the formation of the sidewall. As a result, the dielectric constant or the insulating property of the high dielectric constant gate insulating film is lowered at the end of the gate electrode, so as to disadvantageously degrade the device characteristics and the reliability of the gate insulating film.

In consideration of the aforementioned conventional problem, an object of the invention is improving the characteristics of a MISFET without degrading a high dielectric constant gate insulating film.

In order to achieve the object, the present inventors have made various examinations, resulting in finding the following: When a high dielectric constant insulating film is used as a material for a sidewall instead of a conventional insulating film such as a silicon oxide film, the composition of the side end portion of the high dielectric constant gate insulating film can be prevented from approximating to SiO₂ during the formation of the sidewall. Thus, the dielectric constant and the insulating property of the high dielectric constant gate insulating film can be prevented from lowering at the end of a gate electrode, namely, degradation of the device characteristics and the reliability of the gate insulating film can be prevented.

Also, the present inventors have found a structure of a MISFET and a method for fabricating the same in which a high dielectric constant gate insulating film is allowed to remain below a sidewall so as to prevent the performance degradation of the high dielectric constant gate insulating film derived from the contact between the side end portion of the high dielectric constant gate insulating film and the sidewall. In the case where the high dielectric constant gate insulating film is allowed to remain below the sidewall, the capacitance between the gate and the drain is so increased that the circuit speed is harmfully affected. Also in this case, it is necessary to perform ion implantation for forming an extension region or an LDD (lightly doped drain) region through the high dielectric constant film. At this point, the implantation acceleration energy is so increased for the reasons described below that an implanted impurity extends too largely in the depth direction, in other words, the junction position of the extension region or the LDD region becomes too deep, resulting in a problem that desired device characteristics cannot be attained.

Reason 1: In the case where a high dielectric constant film is used as a gate insulating film, the thickness is set to be large because a desired dielectric constant can be attained without reducing the thickness.

Reason 2: Since a high dielectric constant film includes a heavy metal, the Rp (projection range) of implanted ion seeds is small.

Accordingly, the present inventors have devised a structure of a MISFET and a method for fabricating the same in which a high dielectric constant gate insulating film is allowed to remain below a sidewall and the high dielectric constant gate insulating film has a smaller thickness below the sidewall than below a gate electrode.

Specifically, the first semiconductor device of the invention includes a high dielectric constant gate insulating film formed on an active region of a substrate; a gate electrode formed on the high dielectric constant gate insulating film; and a high dielectric constant insulating sidewall formed on a side face of the gate electrode.

In the first semiconductor device of this invention, since the insulating sidewall formed on the side face of the gate electrode has a high dielectric constant, it is possible to avoid the conventional problem that the composition of a side end portion of the high dielectric constant gate insulating film approximates to SiO₂, which is caused in forming a conventional sidewall made of an insulating film such as a silicon oxide film. Therefore, lowering of the dielectric constant and the insulating property of the high dielectric constant gate insulating film at the end of the gate electrode can be prevented, so as to prevent degradation of the device characteristics and the reliability of the gate insulating film.

In this invention, as the high dielectric constant gate insulating film or the high dielectric constant insulating sidewall, an insulating metal oxide or an insulating metal silicate with a dielectric constant of 8 or more and preferably 10 or more can be specifically used.

In the first semiconductor device of the invention, the high dielectric constant gate insulating film preferably continuously extends from under the gate electrode to under the high dielectric constant insulating sidewall. Thus, since the continuity of the high dielectric constant gate insulating film is kept at the end of the gate electrode, it is possible to more definitely suppress the lowering of the dielectric constant and the insulating property of the high dielectric constant gate insulating film otherwise caused at the end of the gate electrode through direct contact between the side end portion of the high dielectric constant gate insulating film and the sidewall. In this case, the high dielectric constant gate insulating film preferably has a smaller thickness below the high dielectric constant insulating sidewall than below the gate electrode. Thus, increase of capacitance between the gate and the drain can be suppressed so as to reduce harmful influence on a circuit speed. Furthermore, since the thickness of the high dielectric constant film present on the substrate in performing implantation for forming an extension region or an LDD region is small, increase of implantation acceleration energy can be suppressed. Therefore, a shallow junction can be easily formed in the extension region or the LDD region, so as to easily improve the device characteristics.

In the first semiconductor device of the invention, the high dielectric constant insulating sidewall preferably has a lower dielectric constant than the high dielectric constant gate insulating film. Thus, parasitic capacitance of the gate electrode caused (mainly between the gate electrode and a source/drain region) due to the high dielectric constant insulating sidewall can be reduced. Also, in this case, the high dielectric constant insulating sidewall is preferably formed, so as to attain a lower dielectric constant than the high dielectric constant gate insulating film, by using the same material as that used for the high dielectric constant gate insulating film with its composition ratios changed. Thus, the dielectric constant of the high dielectric constant insulating sidewall can be easily made lower than that of the high dielectric constant gate insulating film while suppressing the lowering the dielectric constant and the insulating property of the high dielectric constant gate insulating film.

The second semiconductor device of this invention includes a high dielectric constant gate insulating film formed on an active region of a substrate; a gate electrode formed on the high dielectric constant gate insulating film; a first insulating sidewall formed on a side face of the gate electrode and having a high dielectric constant; and a second insulating sidewall formed above the side face of the gate electrode with the first insulating sidewall sandwiched therebetween.

In the second semiconductor device of this invention, since the first insulating sidewall formed on the side face of the gate electrode has a high dielectric constant, it is possible to avoid the conventional problem that the composition of a side end portion of the high dielectric constant gate insulating film approximates to SiO₂, which is caused in forming a conventional sidewall made of an insulating film such as a silicon oxide film. Therefore, lowering of the dielectric constant and the insulating property of the high dielectric constant gate insulating film at the end of the gate electrode can be prevented, so as to prevent degradation of the device characteristics and the reliability of the gate insulating film.

In the second semiconductor device, the first insulating sidewall may be an offset sidewall or an L-shaped first layer portion of an insulating sidewall having a multilayered structure. Also, the second insulating sidewall of the second semiconductor device may or may not have a high dielectric constant. In the case where the second insulating sidewall is, for example, a SiN portion of an insulating sidewall having a multilayered structure, it is not preferred to replace the SiN portion with a high dielectric constant portion made of an insulating metal oxide or an insulating metal silicate.

In the second semiconductor device of the invention, the high dielectric constant gate insulating film preferably continuously extends from under the gate electrode to under the first insulating sidewall. Thus, since the continuity of the high dielectric constant gate insulating film is kept at the end of the gate electrode, it is possible to more definitely suppress the lowering of the dielectric constant and the insulating property of the high dielectric constant gate insulating film otherwise caused at the end of the gate electrode through direct contact between the side end portion of the high dielectric constant gate insulating film and the sidewall. In this case, the high dielectric constant gate insulating film preferably has a smaller thickness below the first insulating sidewall than below the gate electrode. Thus, increase of capacitance between the gate and the drain can be suppressed so as to reduce harmful influence on a circuit speed. Furthermore, since the thickness of the high dielectric constant film present on the substrate in performing implantation for forming an extension region or an LDD region is small, increase of implantation acceleration energy can be suppressed. Therefore, a shallow junction can be easily formed in the extension region or the LDD region, so as to easily improve the device characteristics.

In the second semiconductor device of the invention, the high dielectric constant gate insulating film preferably continuously extends from under the gate electrode to under the second insulating sidewall. Thus, since the continuity of the high dielectric constant gate insulating film is kept at the end of the gate electrode, it is possible to more definitely suppress the lowering of the dielectric constant and the insulating property of the high dielectric constant gate insulating film otherwise caused at the end of the gate electrode through direct contact between the side end portion of the high dielectric constant gate insulating film and the sidewall. In this case, the high dielectric constant gate insulating film preferably has an equivalent thickness below the first insulating sidewall than below the gate electrode and a smaller thickness below the second insulating sidewall than below the gate electrode. Alternatively, it has a smaller thickness below the first insulating sidewall than below the gate electrode and an equivalent thickness below the second insulating sidewall and below the first insulating sidewall. Alternatively, it has a smaller thickness below the first insulating sidewall than below the gate electrode and a smaller thickness below the second insulating sidewall than below the first insulating sidewall. Thus, the increase of the capacitance between the gate and the drain can be suppressed so as to reduce the harmful influence on the circuit speed. Furthermore, since the thickness of the high dielectric constant film present on the substrate in performing implantation for forming an extension region or an LDD region is small, the increase of implantation acceleration energy can be suppressed. Therefore, a shallow junction can be easily formed in the extension region or the LDD region, so as to easily improve the device characteristics.

In the second semiconductor device of the invention, the first insulating sidewall preferably has a lower dielectric constant than the high dielectric constant gate insulating film. Thus, parasitic capacitance of the gate electrode caused (mainly between the gate electrode and a source/drain region) due to the first insulating sidewall can be reduced. Also, in this case, the first insulating sidewall is preferably formed, so as to attain a lower dielectric constant than the high dielectric constant gate insulating film, by using the same material as that used for the high dielectric constant gate insulating film with its composition ratios changed. Thus, the dielectric constant of the first insulating sidewall can be easily made lower than that of the high dielectric constant gate insulating film while suppressing the lowering of the dielectric constant and the insulating property of the high dielectric constant gate insulating film.

In each of the first and second semiconductor devices of the invention, a notch is preferably provided in a side end portion of the high dielectric constant gate insulating film. Thus, the increase of the capacitance between the gate electrode and the source/drain region can be suppressed so as to reduce the harmful influence on the circuit speed.

In each of the first and second semiconductor devices of the invention, a buffer insulating film is preferably provided between the substrate and the high dielectric constant gate insulating film. Thus, the interface between the substrate and the high dielectric constant gate insulating film can be prevented from degrading. In this case, when the buffer insulating film is made of a silicon oxide film or a silicon nitride film, the effect to prevent the degradation of the interface can be definitely attained.

In each of the first and second semiconductor devices of the invention, the gate electrode is preferably a full silicide gate electrode or a metal gate electrode. Thus, the degree of integration, the performance and the operation speed of the semiconductor device can be definitely improved.

The first method for fabricating a semiconductor device of this invention includes the steps of (a) forming a high dielectric constant gate insulating film on an active region of a substrate; (b) forming a gate electrode on the high dielectric constant gate insulating film; and (c) forming a high dielectric constant insulating sidewall on a side face of the gate electrode.

In the first method for fabricating a semiconductor device of this invention, since the insulating sidewall formed on the side face of the gate electrode has a high dielectric constant, it is possible to avoid the conventional problem that the composition of a side end portion of the high dielectric constant gate insulating film approximates to SiO₂, which is caused in forming a conventional sidewall made of an insulating film such as a silicon oxide film. Therefore, lowering of the dielectric constant and the insulating property of the high dielectric constant gate insulating film at the end of the gate electrode can be prevented, so as to prevent degradation of the device characteristics and the reliability of the gate insulating film.

The first method for fabricating a semiconductor device of this invention preferably further includes, between the step (b) and the step (c), a step of thinning a portion of the high dielectric constant gate insulating film disposed outside the gate electrode. Thus, since the high dielectric constant gate insulating film remains outside the gate electrode and hence the continuity of the high dielectric constant gate insulating film is kept at the end of the gate electrode, it is possible to more definitely suppress the lowering of the dielectric constant and the insulating property of the high dielectric constant gate insulating film otherwise caused at the end of the gate electrode through direct contact between the side end portion of the high dielectric constant gate insulating film and the sidewall. Furthermore, since the high dielectric constant gate insulating film is thinned outside the gate electrode, increase of capacitance between the gate and the drain can be suppressed so as to reduce harmful influence on a circuit speed. Furthermore, since the thickness of the high dielectric constant film present on the substrate in performing implantation for forming an extension region or an LDD region is small, increase of implantation acceleration energy can be suppressed. Therefore, a shallow junction can be easily formed in the extension region or the LDD region, so as to easily improve the device characteristics.

The first method for fabricating a semiconductor device of this invention preferably further includes, after the step (c), a step of removing a portion of the high dielectric constant gate insulating film disposed away from the gate electrode beyond the high dielectric constant insulating sidewall. Thus, the increase of the capacitance between the gate and the drain can be suppressed so as to reduce the harmful influence on the circuit speed.

In the first method for fabricating a semiconductor device of the invention, the high dielectric constant insulating sidewall preferably has a lower dielectric constant than the high dielectric constant gate insulating film. Thus, parasitic capacitance of the gate electrode caused (mainly between the gate electrode and a source/drain region) due to the high dielectric constant insulating sidewall can be reduced. Also, in this case, the step (c) preferably includes a sub-step of forming the high dielectric constant insulating sidewall to have the lower dielectric constant than the high dielectric constant gate insulating film by using the same material as that used for the high dielectric constant gate insulating film with its composition ratios changed. Thus, the dielectric constant of the high dielectric constant insulating sidewall can be easily made lower than that of the high dielectric constant gate insulating film while suppressing the lowering of the dielectric constant and the insulating property of the high dielectric constant gate insulating film.

The second method for fabricating a semiconductor device of this invention includes the steps of (a) forming a high dielectric constant gate insulating film on an active region of a substrate; (b) forming a gate electrode on the high dielectric constant gate insulating film; (c) forming a first insulating sidewall having a high dielectric constant on a side face of the gate electrode; and (d) forming a second insulating sidewall above the side face of the gate electrode with the first insulating sidewall sandwiched therebetween.

In the second method for fabricating a semiconductor device of this invention, since the first insulating sidewall formed on the side face of the gate electrode has a high dielectric constant, it is possible to avoid the conventional problem that the composition of a side end portion of the high dielectric constant gate insulating film approximates to SiO₂, which is caused in forming a conventional sidewall made of an insulating film such as a silicon oxide film. Therefore, lowering of the dielectric constant and the insulating property of the high dielectric constant gate insulating film at the end of the gate electrode can be prevented, so as to prevent degradation of the device characteristics and the reliability of the gate insulating film.

In the second method for fabricating a semiconductor device of this invention, the first insulating sidewall may be an offset sidewall or an L-shaped first layer portion of an insulating sidewall having a multilayered structure. Also, in the second method for fabricating a semiconductor device of this invention, the second insulating sidewall may or may not have a high dielectric constant, and in the case where the second insulating sidewall is, for example, a SiN portion of an insulating sidewall having a multilayered structure, it is not preferred to replace the SiN portion with a high dielectric constant portion made of an insulating metal oxide or an insulating metal silicate.

The second method for fabricating a semiconductor device of this invention preferably further includes, between the step (b) and the step (c), a step of thinning a portion of the high dielectric constant gate insulating film disposed outside the gate electrode. Thus, since the high dielectric constant gate insulating film remains outside the gate electrode and hence the continuity of the high dielectric constant gate insulating film is kept at the end of the gate electrode, it is possible to more definitely suppress the lowering of the dielectric constant and the insulating property of the high dielectric constant gate insulating film otherwise caused at the end of the gate electrode through direct contact between the side end portion of the high dielectric constant gate insulating film and the sidewall. Furthermore, since the high dielectric constant gate insulating film is thinned outside the gate electrode, increase of capacitance between the gate and the drain can be suppressed so as to reduce harmful influence on a circuit speed. Furthermore, since the thickness of the high dielectric constant film present on the substrate in performing implantation for forming an extension region or an LDD region is small, increase of implantation acceleration energy can be suppressed. Therefore, a shallow junction can be easily formed in the extension region or the LDD region, so as to easily improve the device characteristics.

The second method for fabricating a semiconductor device of this invention preferably further includes, between the step (c) and the step (d), a step of removing a portion of the high dielectric constant gate insulating film disposed away from the gate electrode beyond the first insulating sidewall. Alternatively, the second method for fabricating a semiconductor device of this invention preferably further includes steps of thinning a portion of the high dielectric constant gate insulating film disposed away from the gate electrode beyond the first insulating sidewall between the step (c) and the step (d); and removing a portion of the high dielectric constant gate insulating film disposed away from the gate electrode beyond the second insulating sidewall after the step (d). Thus, increase of the capacitance between the gate and the drain can be suppressed so as to reduce the harmful influence of the circuit speed.

In the second method for fabricating a semiconductor device of the invention, the step (b) preferably includes a sub-step of forming a protection film for covering a top face of the gate electrode, and the method preferably further includes, after the step (d), a step of siliciding a surface portion of the active region disposed away from the gate electrode beyond the second insulating sidewall, removing the protection film and full siliciding the gate electrode. Thus, a semiconductor device having a full silicide gate electrode can be easily realized.

In the second method for fabricating a semiconductor device of the invention, the first insulating sidewall preferably has a lower dielectric constant than the high dielectric constant gate insulating film. Thus, the parasitic capacitance of the gate electrode caused (mainly between the gate electrode and a source/drain region) due to the first insulating sidewall can be reduced. Also, in this case, the step (c) preferably includes a sub-step of forming the high dielectric constant insulating sidewall to have the lower dielectric constant than the high dielectric constant gate insulating film by using the same material as that used for the high dielectric constant gate insulating film with its composition ratios changed. Thus, the dielectric constant of the first insulating sidewall can be easily made lower than that of the high dielectric constant gate insulating film while suppressing the lowering of the dielectric constant and the insulating property of the high dielectric constant gate insulating film.

In each of the first and second methods for fabricating a semiconductor device of the invention, the high dielectric constant gate insulating film is preferably selectively removed by wet etching. Thus, the high dielectric constant gate insulating film can be easily removed. Furthermore, since a notch can be provided in a side end portion of the high dielectric constant gate insulating film by the wet etching, the increase of the capacitance between the gate electrode and the source/drain region can be suppressed so as to reduce the harmful influence of the circuit speed.

Each of the first and second methods for fabricating a semiconductor device of the invention preferably further includes, before the step (a), a step of forming a buffer insulating film on the active region, and the high dielectric constant gate insulating film is preferably formed above the active region with the buffer insulating film sandwiched therebetween in the step (a). Thus, degradation of the interface between the substrate and the high dielectric constant gate insulating film can be prevented.

As described above, according to the present invention, since the insulating sidewall formed on the side face of the gate electrode has a high dielectric constant, it is possible to avoid the conventional problem that the composition of the side end portion of the high dielectric constant gate insulating film approximates to SiO₂, which is caused in forming a conventional sidewall made of an insulating film such as a silicon oxide film. Therefore, the lowering of the dielectric constant and the insulating property of the high dielectric constant gate insulating film otherwise caused at the end of the gate electrode can be prevented, so as to prevent degradation of the device characteristics and the reliability of the gate insulating film.

Furthermore, according to the present invention, since the high dielectric constant gate insulating film is formed so as to continuously extend from under the gate electrode to under the insulating sidewall, namely, since the continuity of the high dielectric constant gate insulating film is kept at the end of the gate electrode, it is possible to definitely suppress the lowering of the dielectric constant and the insulating property of the high dielectric constant gate insulating film otherwise caused at the end of the gate electrode through direct contact between the side end portion of the high dielectric constant gate insulating film and the sidewall film.

Moreover, according to the present invention, since the high dielectric constant gate insulating film has a smaller thickness below the insulating sidewall than below the gate electrode, the increase of the capacitance between the gate and the drain can be suppressed so as to reduce the harmful influence on the circuit speed. Furthermore, since the high dielectric constant film present on the substrate in performing implantation for forming an extension region or an LDD region has a small thickness, the increase of the implantation acceleration energy can be suppressed. Therefore, a shallow junction can be easily formed in the extension region or the LDD region, so as to easily improve the device characteristics.

In this manner, the present invention relates to a semiconductor device and a method for fabricating the same and is very useful particularly in application to a MISFET having a high dielectric constant gate insulating film for attaining an effect to improve the driving power and the reliability of the MISFET.

### BRIEF DESCRIPTION of THE DRAWINGS

FIG. 1 is a cross-sectional view for showing the structure of a semiconductor device according to Embodiment 1 of the invention;

FIGS. 2A and 2B are cross-sectional views for showing the structures of an insulating sidewall used in the semiconductor device of Embodiment 1;

FIG. 3 is a cross-sectional view for showing the structure of a semiconductor device according to Modification 1 of Embodiment 1 of the invention;

FIG. 4 is a cross-sectional view for showing the structure of a semiconductor device according to Modification 2 of Embodiment 1 of the invention;

FIG. 5 is a cross-sectional view for showing the structure of a semiconductor device according to Modification 3 of Embodiment 1 of the invention;

FIG. 6 is a cross-sectional view for showing the structure of a semiconductor device according to Embodiment 2 of the invention;

FIGS. 7A and 7B are cross-sectional views for showing the structures of an insulating sidewall used in the semiconductor device of Embodiment 2 of the invention;

FIG. 8 is a cross-sectional view for showing the structure of a semiconductor device according to Modification 1 of Embodiment 2 of the invention;

FIG. 9 is a cross-sectional view for showing the structure of a semiconductor device according to Modification 2 of Embodiment 2 of the invention;

FIG. 10 is a cross-sectional view for showing the structure of a semiconductor device according to Modification 3 of Embodiment 2 of the invention;

FIG. 11 is a cross-sectional view for showing the structure of a semiconductor device according to Embodiment 3 of the invention;

FIG. 12 is a cross-sectional view for showing the structure of a semiconductor device according to a modification of Embodiment 3 of the invention;

FIG. 13 is a cross-sectional view for showing the structure of a semiconductor device according to another modification of Embodiment 3 of the invention;

FIG. 14 is a cross-sectional view for showing the structure of a semiconductor device according to another modification of Embodiment 3 of the invention;

FIG. 15 is a cross-sectional view for showing the structure of a semiconductor device according to another modification of Embodiment 3 of the invention;

FIG. 16 is a cross-sectional view for showing the structure of a semiconductor device according to Embodiment 4 of the invention;

FIG. 17 is a cross-sectional view for showing the structure of a semiconductor device according to a modification of Embodiment 4 of the invention;

FIG. 18 is a cross-sectional view for showing the structure of a semiconductor device according to another modification of Embodiment 4 of the invention;

FIG. 19 is a cross-sectional view for showing the structure of a semiconductor device according to another modification of Embodiment 4 of the invention;

FIGS. 20A, 20B, 20C, 20D, 20E and 20F are cross-sectional views for showing procedures in a method for fabricating a semiconductor device according to Embodiment 5 of the invention;

FIGS. 21A, 21B, 21C, 21D, 21E, 21F and 21G are cross-sectional views for showing procedures in a method for fabricating a semiconductor device according to Embodiment 6 of the invention;

FIGS. 22A, 22B, 22C, 22D, 22E, 22F and 22G are cross-sectional views for showing procedures in a method for fabricating a semiconductor device according to Embodiment 7 of the invention;

FIGS. 23A, 23B, 23C, 23D, 23E, 23F and 23G are cross-sectional views for showing procedures in a method for fabricating a semiconductor device according to Embodiment 8 of the invention;

FIGS. 24A, 24B, 24C and 24D are cross-sectional views for showing other procedures in the method for fabricating a semiconductor device according to Embodiment 8 of the invention;

FIG. 25 is a cross-sectional view for showing a notch provided in the semiconductor device of Modification 2 of Embodiment 1 shown in FIG. 3;

FIG. 26 is a cross-sectional view for showing a notch provided in the semiconductor device of Modification 2 of Embodiment 2 shown in FIG. 9;

FIG. 27 is a cross-sectional view for showing a notch provided in the semiconductor device of the modification of Embodiment 3 shown in FIG. 14;

FIG. 28 is a cross-sectional view for showing a notch provided in the semiconductor device of Modification 2 of Embodiment 1 shown in FIG. 3;

FIG. 29 is a cross-sectional view for showing a notch provided in the semiconductor device of Modification 2 of Embodiment 2 shown in FIG. 9;

FIG. 30 is a cross-sectional view for showing a notch provided in the semiconductor device of the modification of Embodiment 3 shown in FIG. 14; and

FIGS. 31A and 31B are cross-sectional views for showing the structures of conventional MISFETs.

### DETAILED DESCRIPTION of THE INVENTION

### Embodiment 1

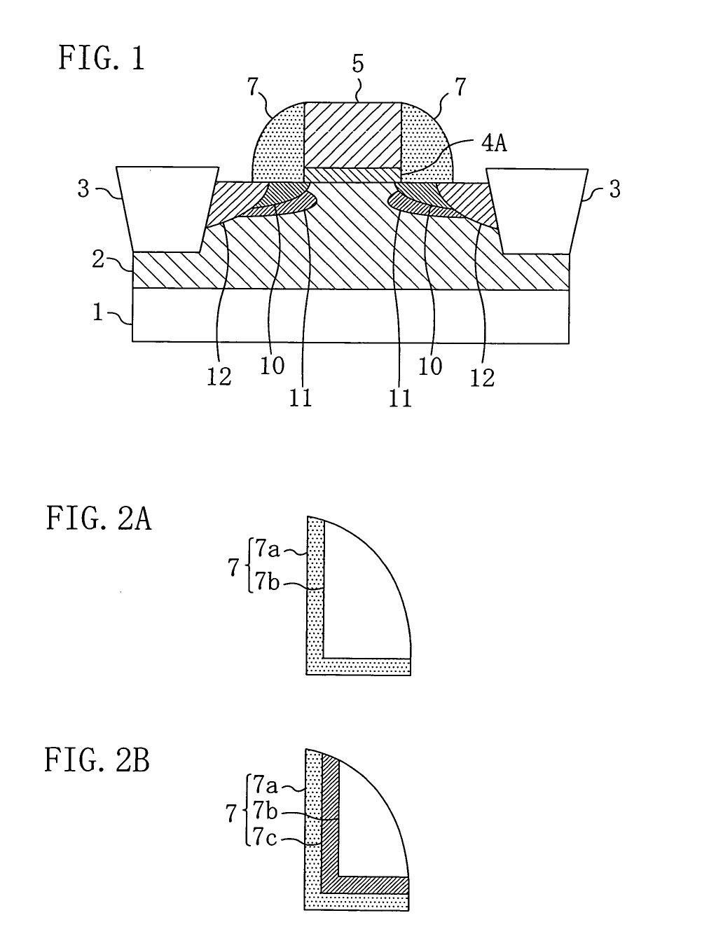

A semiconductor device according to Embodiment 1 of the invention will now be described with reference to the accompanying drawings. FIG. 1 is a cross-sectional view for showing the structure of the semiconductor device (specifically, a single sidewall type MISFET) of Embodiment 1.

As shown in FIG. 1, a gate electrode 5 is formed on a portion, surrounded with an STI 3, of a P-type well 2 corresponding to an active region of a substrate 1 of, for example, silicon with a high dielectric constant gate insulating film 4A of, for example, HfO₂, HfSiO₂, HfSiON or HfAlOₓ sandwiched therebetween. An insulating sidewall 7 having a high dielectric constant is formed on the side face of the gate electrode 5. An N-type extension region 10 is formed in a portion of the well 2 disposed below the sidewall 7, and a P-type pocket region 11 is formed in a portion of the well 2 disposed below the extension region 10. An N-type source/drain region 12 is formed in a portion of the well 2 disposed away from the gate electrode 5 beyond the extension region 10 and the pocket region 11.

As a characteristic of this embodiment, the insulating sidewall 7 is made of a high dielectric constant insulating film of, for example, HfO₂, HfSiO₂, HfSiON or HfAlOₓ.

According to this embodiment, since the insulating sidewall 7 formed on the side face of the gate electrode 5 has a high dielectric constant, it is possible to avoid the conventional problem that the composition of a side end portion of the high dielectric constant gate insulating film 4A approximates to SiO₂, which is caused through the contact between the side end portion of the high dielectric constant insulating film 4A and a conventional insulating film during the formation of a sidewall made of the conventional insulating film such as a silicon oxide film. Therefore, lowering of the dielectric constant and the insulating property of the high dielectric constant gate insulating film 4A otherwise caused at the end of the gate electrode 5 can be prevented, so as to prevent degradation of the device characteristics and the reliability of the gate insulating film.

Furthermore, in this embodiment, since the insulating sidewall 7 formed on the side face of the gate electrode 5 has a high dielectric constant, the capacitive coupling between the gate electrode 5 and the extension region 10 is increased in the vicinity of the end of the gate electrode 5, and hence, a high gate/drain overlap effect can be attained. Therefore, the device characteristics and the hot charier resistance can be improved (see, for example, Non-patent document 2 mentioned above).

In this embodiment, the dielectric constant of the insulating sidewall 7 is preferably lower than that of the high dielectric constant gate insulating film 4A. Thus, parasitic capacitance of the gate electrode 5 caused (mainly between the gate electrode 5 and the source/drain region 12) due to the insulating sidewall 7 can be reduced. Also, in this case, the insulating sidewall 7 is preferably formed, so as to attain a lower dielectric constant than the high dielectric constant gate insulating film 4A, by using the same material as that used for the high dielectric constant gate insulating film 4A with its composition ratios changed. Thus, the dielectric constant of the insulating sidewall 7 can be easily made lower than that of the high dielectric constant gate insulating film 4A while suppressing the lowering of the dielectric constant and the insulating property of the high dielectric constant gate insulating film 4A.

Although the insulating sidewall 7 of this embodiment has a single-layered structure, the insulating sidewall 7 may have a multilayered structure including two or more layers as shown in, for example, FIGS. 2A and 2B instead. At this point, FIG. 2A shows an exemplified cross-sectional structure of a sidewall having a two-layered structure. This insulating sidewall 7 is composed of an L-shaped lower portion 7a and an upper portion 7b, at least the lower portion 7a is made of a high dielectric constant material and the upper portion 7b is made of, for example, SiN (silicon nitride; which also applies in the following description). Alternatively, FIG. 2B shows an exemplified cross-sectional structure of a sidewall having a three-layered structure. This insulating sidewall 7 is composed of an L-shaped lower portion 7a, an intermediate portion 7c and an upper portion 7b, at least the lower portion 7a is made of a high dielectric constant material, the intermediate portion 7c is made of, for example, SiN, and the upper portion 7b is made of, for example, SiO₂.

Furthermore, in this embodiment, the gate electrode 5 is preferably a full silicide gate electrode or a metal gate electrode. Thus, the degree of integration, the performance and the operation speed of the semiconductor device can be definitely improved.

### Modification 1 of Embodiment 1

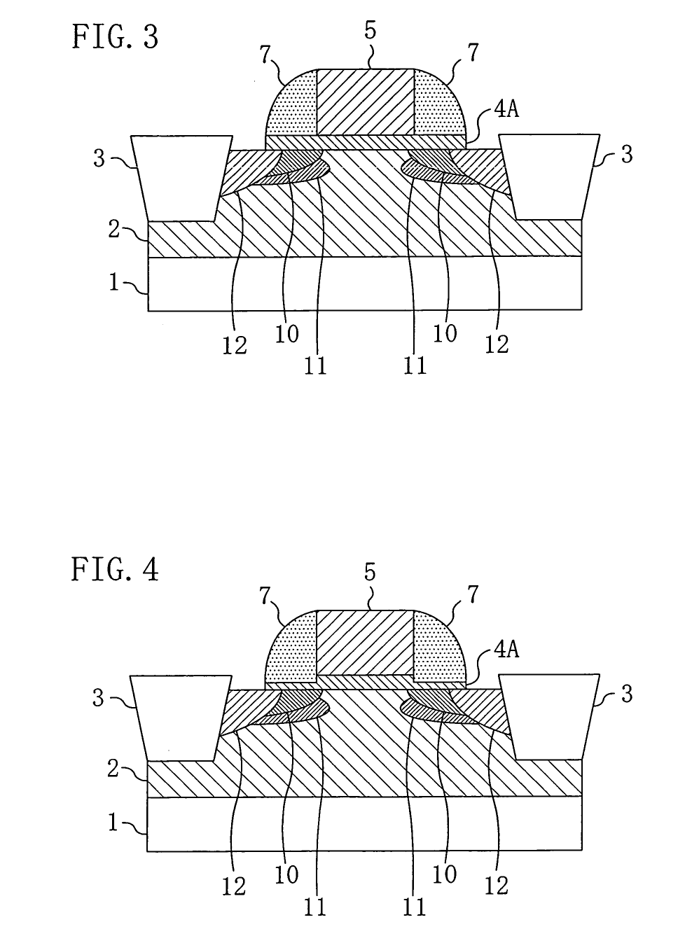

A semiconductor device according to Modification 1 of Embodiment 1 of the invention will now be described with reference to the accompanying drawing. FIG. 3 is a cross-sectional view for showing the structure of the semiconductor device (specifically, a single sidewall type MISFET) according to Modification 1 of Embodiment 1.

This modification is different from Embodiment 1 in the high dielectric constant gate insulating film 4A present not only below the gate electrode 5 but also below the insulating sidewall 7 as shown in FIG. 3. In other words, the high dielectric constant gate insulating film 4A is formed so as to continuously extend from under the gate electrode 5 to under the insulating sidewall 7.

According to this modification, the following effects can be attained in addition to the effects attained in Embodiment 1: Since the high dielectric constant gate insulating film 4A is formed so as to continuously extend from under the gate electrode 5 to under the insulating sidewall 7, the continuity of the high dielectric constant gate insulating film 4A is kept at the end of the gate electrode 5, and therefore, a side end portion of the high dielectric constant gate insulating film 4A is never in direct contact with a conventional sidewall film such as a silicon oxide film at the end of the gate electrode 5. Accordingly, the lowering of the dielectric constant and the insulating property of the high dielectric constant gate insulating film 4A otherwise caused at the end of the gate electrode 5 can be more definitely suppressed, and therefore, the degradation of the device characteristics and the reliability of the gate insulating film can be more definitely prevented.

Moreover, according to this modification, since the high dielectric constant gate insulating film 4A is formed so as to continuously extend from under the gate electrode 5 to under the insulating sidewall 7, the capacitive coupling between the gate electrode 5 and the extension region 10 is increased in the vicinity of the end of the gate electrode 5, resulting in attaining a high gate/drain overlap effect. Accordingly, the device characteristics and the hot carrier resistance can be improved (see, for example, Non-patent document 2 mentioned above).

Also in this modification, the dielectric constant of the insulating sidewall 7 is preferably lower than that of the high dielectric constant gate insulating film 4A. Thus, the parasitic capacitance of the gate electrode 5 caused (mainly between the gate electrode 5 and the source/drain region 12) due to the insulating sidewall 7 can be reduced. Also, in this case, the insulating sidewall 7 is preferably formed, so as to attain a lower dielectric constant than the high dielectric constant gate insulating film 4A, by using the same material as that used for the high dielectric constant gate insulating film 4A with its composition ratios changed. Thus, the dielectric constant of the insulating sidewall 7 can be easily made lower than that of the high dielectric constant gate insulating film 4A while suppressing the lowering of the dielectric constant and the insulating property of the high dielectric constant gate insulating film 4A.

Also in this modification, the insulating sidewall 7 may have a multilayered structure shown in, for example, FIG. 2A or 2B (see Embodiment 1).

Furthermore, the gate electrode 5 is preferably a full silicide gate electrode or a metal gate electrode also in this modification. Thus, the degree of integration, the performance and the operation speed of the semiconductor device can be definitely improved.

### Modification 2 of Embodiment 1

A semiconductor device according to Modification 2 of Embodiment 1 of the invention will now be described with reference to the accompanying drawing. FIG. 4 is a cross-sectional view for showing the structure of the semiconductor device (specifically, a single sidewall type MISFET) according to Modification 2 of Embodiment 1.

This modification is different from Embodiment 1 in the high dielectric constant gate insulating film 4A present not only below the gate electrode 5 but also below the insulating sidewall 7 and the high dielectric constant gate insulating film 4A having a smaller thickness below the insulating sidewall 7 than below the gate electrode 5 as shown in FIG. 4. In other words, the high dielectric constant gate insulating film 4A is formed in a convex shape in this modification.

According to this modification, the following effects can be attained in addition to the effects attained in Embodiment 1: Since the high dielectric constant gate insulating film 4A is formed so as to continuously extend from under the gate electrode 5 to under the insulating sidewall 7, the continuity of the high dielectric constant gate insulating film 4A is kept at the end of the gate electrode 5, and therefore, the side end portion of the high dielectric constant gate insulating film 4A is never in direct contact with a conventional sidewall film such as a silicon oxide film at the end of the gate electrode 5. Accordingly, the lowering of the dielectric constant and the insulating property of the high dielectric constant gate insulating film 4A otherwise caused at the end of the gate electrode 5 can be more definitely suppressed, and therefore, the degradation of the device characteristics and the reliability of the gate insulating film can be more definitely prevented.

Moreover, according to this modification, since the high dielectric constant gate insulating film 4A is formed so as to continuously extend from under the gate electrode 5 to under the insulating sidewall 7, the capacitive coupling between the gate electrode 5 and the extension region 10 is increased in the vicinity of the end of the gate electrode 5, resulting in attaining a high gate/drain overlap effect. Accordingly, the device characteristics and the hot carrier resistance can be improved (see, for example, Non-patent document 2 mentioned above).

Furthermore, according to this modification, since the high dielectric constant gate insulating film 4A has a smaller thickness below the insulating sidewall 7 than below the gate electrode 5, the increase of gate/drain capacitance can be suppressed so as to reduce the harmful influence on the circuit speed. Moreover, since the high dielectric constant film present on the substrate in implantation for forming an extension or LDD region has a small thickness, the increase of the implantation acceleration energy can be suppressed. Therefore, a shallow junction can be easily formed in forming the extension or LDD region, resulting in easily improving the device characteristics.

Also in this modification, the dielectric constant of the insulating sidewall 7 is preferably lower than that of the high dielectric constant gate insulating film 4A. Thus, the parasitic capacitance of the gate electrode 5 caused (mainly between the gate electrode 5 and the source/drain region 12) due to the insulating sidewall 7 can be reduced. Also, in this case, the insulating sidewall 7 is preferably formed, so as to attain a lower dielectric constant than the high dielectric constant gate insulating film 4A, by using the same material as that used for the high dielectric constant gate insulating film 4A with its composition ratios changed. Thus, the dielectric constant of the insulating sidewall 7 can be easily made lower than that of the high dielectric constant gate insulating film 4A while suppressing the lowering of the dielectric constant and the insulating property of the high dielectric constant gate insulating film 4A, namely, while keeping high the dielectric constant of the high dielectric constant gate insulating film 4A below the end of the gate electrode 5.

Also in this modification, the insulating sidewall 7 may have a multilayered structure shown in, for example, FIG. 2A or 2B (see Embodiment 1).

Furthermore, the gate electrode 5 is preferably a full silicide gate electrode or a metal gate electrode also in this modification. Thus, the degree of integration, the performance and the operation speed of the semiconductor device can be definitely improved.

### Modification 3 of Embodiment 1

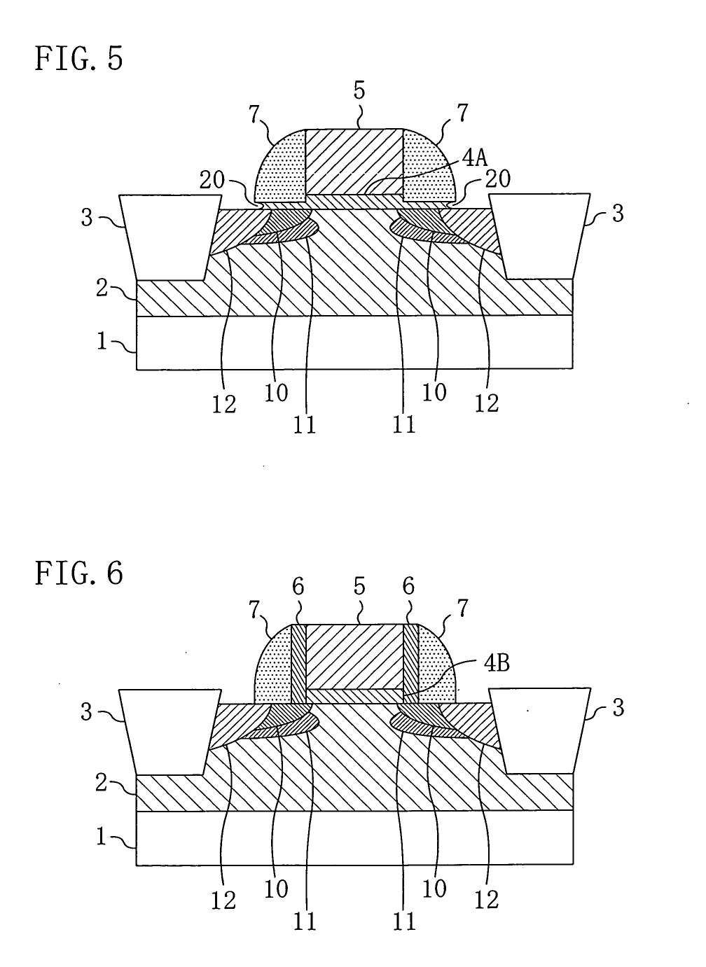

A semiconductor device according to Modification 3 of Embodiment 1 of the invention will now be described with reference to the accompanying drawing. FIG. 5 is a cross-sectional view for showing the structure of the semiconductor device (specifically, a single sidewall type MISFET) according to Modification 3 of Embodiment 1. It goes without saying that the sidewall of the semiconductor device of this modification may have a multilayered structure shown in, for example, FIG. 2A or 2B. It is noted that this modification is obtained by further modifying Modification 2 of Embodiment 1.

This modification is different from Modification 2 of Embodiment 1 in a notch 20 provided in a side end portion of the high dielectric constant gate insulating film 4A and formed by removing a part of the high dielectric constant gate insulating film 4A below the insulating sidewall 7 as shown in FIG. 5.

According to this modification, not only the same effects as those attained in Embodiment 1 can be attained but also the harmful influence on the circuit speed derived from the increase of the capacitance between the gate electrode 5 and the source/drain region 12 can be further suppressed.

Needless to say, the effects similar to those of this modification can be attained by additionally providing the aforementioned characteristic of this modification to Embodiment 1 or Modification 1 thereof.

### Embodiment 2

A semiconductor device according to Embodiment 2 of the invention will now be described with reference to the accompanying drawing. Although the single sidewall type MISFET is described in Embodiment 1, a double sidewall type MISFET (see Non-patent document 3 mentioned above) in which overlap between a gate electrode and an extension region can be easily optimized is described in Embodiment 2.

FIG. 6 is a cross-sectional view for showing the structure of the semiconductor device of Embodiment 2. As shown in FIG. 6, a gate electrode 5 is formed on a portion, surrounded with an STI 3, of a P-type well 2 corresponding to an active region of a substrate 1 of, for example, silicon with a high dielectric constant gate insulating film 4B of, for example, HfO₂, HfSiO₂, HfSiON or HfAlOₓ sandwiched therebetween. An insulating sidewall 7 is formed above the side face of the gate electrode 5 with an insulating offset sidewall 6 having a high dielectric constant sandwiched therebetween. An N-type extension region 10 is formed in a portion of the well 2 disposed below the insulating offset sidewall 6 and the insulating sidewall 7, and a P-type pocket region 11 is formed in a portion of the well 2 disposed below the extension region 10. An N-type source/drain region 12 is formed in a portion of the well 2 disposed away from the gate electrode 5 beyond the extension region 10 and the pocket region 11.

As a characteristic of this embodiment, the insulating offset sidewall 6 is made of a high dielectric constant insulating film of, for example, HfO₂, HfSiO₂, HfSiON or HfAlOₓ.

According to this embodiment, since the insulating offset sidewall 6 formed on the side face of the gate electrode 5 has a high dielectric constant, it is possible to avoid the conventional problem that the composition of a side end portion of the high dielectric constant gate insulating film 4B approximates to SiO₂, which is caused through the contact between the side end portion of the high dielectric constant insulating film 4B and a conventional insulating film during the formation of an offset sidewall made of the conventional insulating film such as a silicon oxide film. Therefore, lowering of the dielectric constant and the insulating property of the high dielectric constant gate insulating film 4B otherwise caused at the end of the gate electrode 5 can be prevented, so as to prevent the degradation of the device characteristics and the reliability of the gate insulating film.

Furthermore, in this embodiment, since the insulating offset sidewall 6 formed on the side face of the gate electrode 5 has a high dielectric constant, the capacitive coupling between the gate electrode 5 and the extension region 10 is increased in the vicinity of the end of the gate electrode 5, and hence, a high gate/drain overlap effect can be attained. Therefore, the device characteristics and the hot charier resistance can be improved (see, for example, Non-patent document 2 mentioned above).

In this embodiment, the dielectric constant of the insulating offset sidewall 6 is preferably lower than that of the high dielectric constant gate insulating film 4B. Thus, parasitic capacitance of the gate electrode 5 caused (mainly between the gate electrode 5 and the source/drain region 12) due to the insulating offset sidewall 6 can be reduced. Also, in this case, the insulating offset sidewall 6 is preferably formed, so as to attain a lower dielectric constant than the high dielectric constant gate insulating film 4B, by using the same material as that used for the high dielectric constant gate insulating film 4B with its composition ratios changed. Thus, the dielectric constant of the insulating offset sidewall 6 can be easily made lower than that of the high dielectric constant gate insulating film 4B while suppressing the lowering of the dielectric constant and the insulating property of the high dielectric constant gate insulating film 4B.

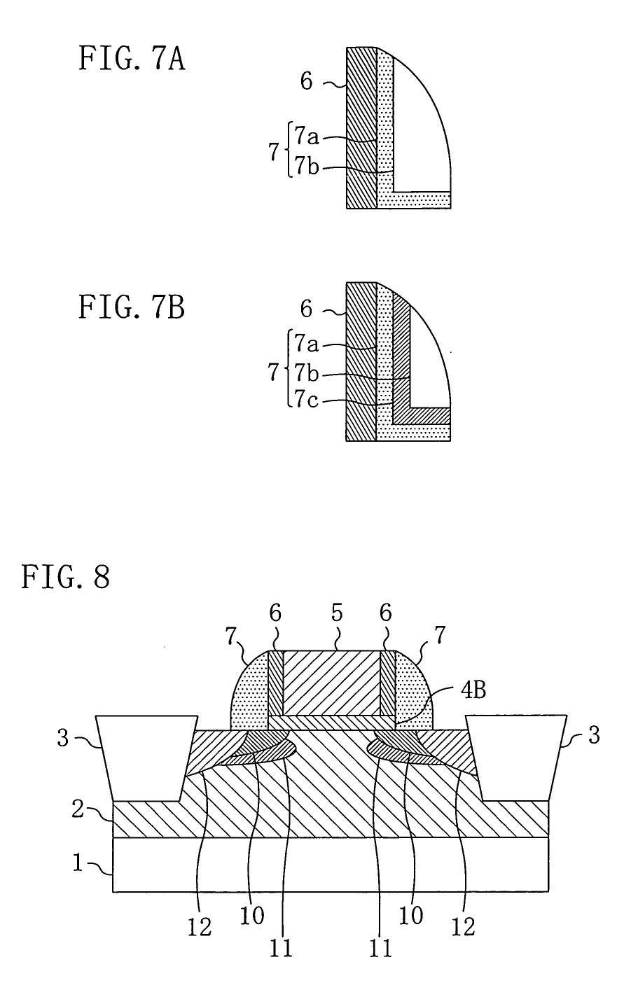

In this embodiment, the insulating sidewall 7 may or may not have a high dielectric constant. Although the insulating sidewall 7 of this embodiment has a single-layered structure, the insulating sidewall 7 may have a multilayered structure including two or more layers as shown in, for example, FIGS. 7A and 7B instead. At this point, FIG. 7A shows an exemplified cross-sectional structure of an insulating sidewall having a two-layered structure. This insulating sidewall 7 is composed of an L-shaped lower portion 7a and an upper portion 7b, the lower portion 7a is made of a high dielectric constant material or SiO₂ and the upper portion 7b is made of, for example, SiN. Alternatively, FIG. 7B shows an exemplified cross-sectional structure of a sidewall having a three-layered structure. This insulating sidewall 7 is composed of an L-shaped lower portion 7a, an intermediate portion 7c and an upper portion 7b, the lower portion 7a is made of a high dielectric constant material or SiO₂, the intermediate portion 7c is made of, for example, SiN, and the upper portion 7b is made of, for example, SiO₂.

Furthermore, in this embodiment, the gate electrode 5 is preferably a full silicide gate electrode or a metal gate electrode. Thus, the degree of integration, the performance and the operation speed of the semiconductor device can be definitely improved.

### Modification 1 of Embodiment 2

A semiconductor device according to Modification 1 of Embodiment 2 of the invention will now be described with reference to the accompanying drawing. FIG. 8 is a cross-sectional view for showing the structure of the semiconductor device (specifically, a double sidewall type MISFET) according to Modification 1 of Embodiment 2.

This modification is different from Embodiment 2 in the high dielectric constant gate insulating film 4B present not only below the gate electrode 5 but also below the insulating offset sidewall 6 as shown in FIG. 8. In other words, the high dielectric constant gate insulating film 4B is formed so as to continuously extend from under the gate electrode 5 to under the insulating offset sidewall 6.

According to this modification, the following effects can be attained in addition to the effects attained in Embodiment 2: Since the high dielectric constant gate insulating film 4B is formed so as to continuously extend from under the gate electrode 5 to under the insulating offset sidewall 6, the continuity of the high dielectric constant gate insulating film 4B is kept at the end of the gate electrode 5, and therefore, a side end portion of the high dielectric constant gate insulating film 4B is never in direct contact with a conventional sidewall film such as a silicon oxide film at the end of the gate electrode 5. Accordingly, the lowering of the dielectric constant and the insulating property of the high dielectric constant gate insulating film 4B otherwise caused at the end of the gate electrode 5 can be more definitely suppressed, and therefore, the degradation of the device characteristics and the reliability of the gate insulating film can be more definitely prevented.

Moreover, according to this embodiment, since the high dielectric constant gate insulating film 4B is formed so as to continuously extend from under the gate electrode 5 to under the insulating offset sidewall 6, the capacitive coupling between the gate electrode 5 and the extension region 10 is increased in the vicinity of the end of the gate electrode 5, resulting in attaining a high gate/drain overlap effect. Accordingly, the device characteristics and the hot carrier resistance can be improved (see, for example, Non-patent document 2 mentioned above).

Also in this modification, the dielectric constant of the insulating offset sidewall 6 is preferably lower than that of the high dielectric constant gate insulating film 4B. Thus, the parasitic capacitance of the gate electrode 5 caused (mainly between the gate electrode 5 and the source/drain region 12) due to the insulating offset sidewall 6 can be reduced. Also, in this case, the insulating offset sidewall 6 is preferably formed, so as to attain a lower dielectric constant than the high dielectric constant gate insulating film 4B, by using the same material as that used for the high dielectric constant gate insulating film 4B with its composition ratios changed. Thus, the dielectric constant of the insulating offset sidewall 6 can be easily made lower than that of the high dielectric constant gate insulating film 4B while suppressing the lowering of the dielectric constant and the insulating property of the high dielectric constant gate insulating film 4B.

Also in this modification, the insulating sidewall 7 may or may not have a high dielectric constant. Furthermore, the insulating sidewall 7 may have a multilayered structure shown in, for example, FIG. 7A or 7B also in this modification (see Embodiment 2).

Furthermore, the gate electrode 5 is preferably a full silicide gate electrode or a metal gate electrode also in this modification. Thus, the degree of integration, the performance and the operation speed of the semiconductor device can be definitely improved.

### Modification 2 of Embodiment 2

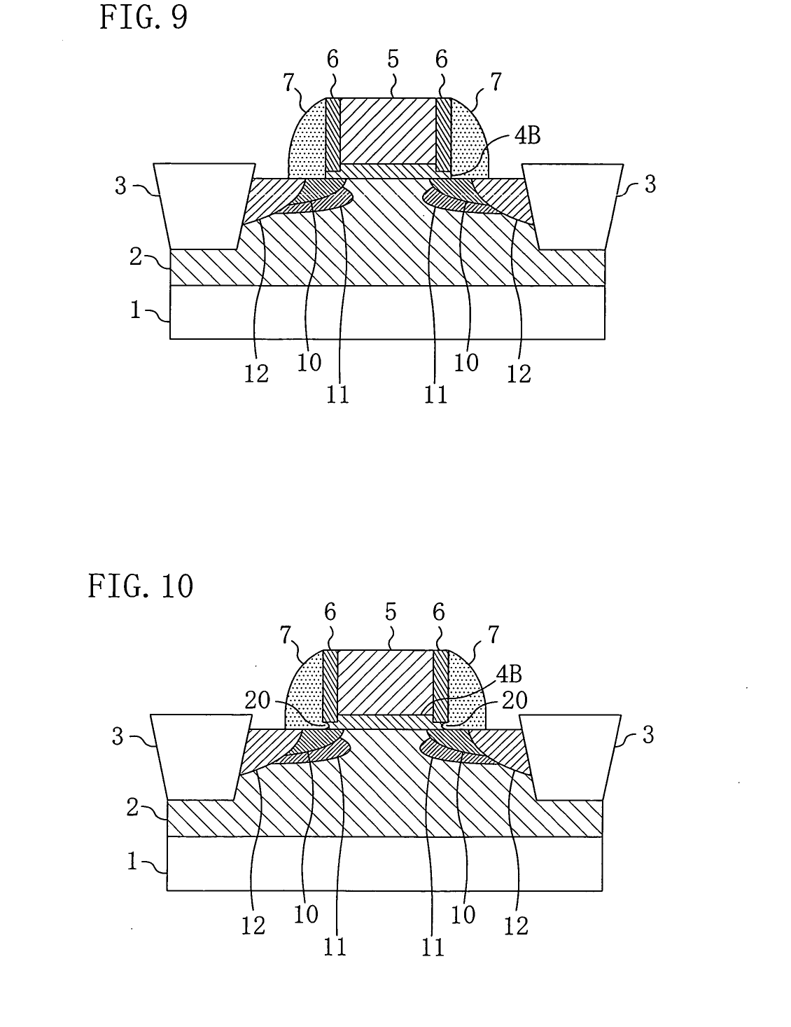

A semiconductor device according to Modification 2 of Embodiment 2 of the invention will now be described with reference to the accompanying drawing. FIG. 9 is a cross-sectional view for showing the structure of the semiconductor device (specifically, a double sidewall type MISFET) according to Modification 2 of Embodiment 2.

This modification is different from Embodiment 2 in the high dielectric constant gate insulating film 4B present not only below the gate electrode 5 but also below the insulating offset sidewall 6 and the high dielectric constant gate insulating film 4B having a smaller thickness below the insulating offset sidewall 6 than below the gate electrode 5 as shown in FIG. 9. In other words, the high dielectric constant gate insulating film 4B is formed in a convex shape in this modification.

According to this modification, the following effects can be attained in addition to the effects attained in Embodiment 2: Since the high dielectric constant gate insulating film 4B is formed so as to continuously extend from under the gate electrode 5 to under the insulating offset sidewall 6, the continuity of the high dielectric constant gate insulating film 4B is kept at the end of the gate electrode 5, and therefore, the side end portion of the high dielectric constant gate insulating film 4B is never in direct contact with a conventional sidewall film such as a silicon oxide film at the end of the gate electrode 5. Accordingly, the lowering of the dielectric constant and the insulating property of the high dielectric constant gate insulating film 4B otherwise caused at the end of the gate electrode 5 can be more definitely suppressed, and therefore, the degradation of the device characteristics and the reliability of the gate insulating film can be more definitely prevented.

Moreover, according to this modification, since the high dielectric constant gate insulating film 4B is formed so as to continuously extend from under the gate electrode 5 to under the insulating offset sidewall 6, the capacitive coupling between the gate electrode 5 and the extension region 10 is increased in the vicinity of the end of the gate electrode 5, resulting in attaining a high gate/drain overlap effect. Accordingly, the device characteristics and the hot carrier resistance can be improved (see, for example, Non-patent document 2 mentioned above).

Furthermore, according to this modification, since the high dielectric constant gate insulating film 4B has a smaller thickness below the insulating offset sidewall 6 than below the gate electrode 5, the increase of gate/drain capacitance can be suppressed so as to reduce the harmful influence on the circuit speed. Moreover, since the high dielectric constant film present on the substrate in the implantation for forming an extension or LDD region has a small thickness, the increase of the implantation acceleration energy can be suppressed. Therefore, a shallow junction can be easily formed in the extension or LDD region, resulting in easily improving the device characteristics.

Also in this modification, the dielectric constant of the insulating offset sidewall 6 is preferably lower than that of the high dielectric constant gate insulating film 4B. Thus, the parasitic capacitance of the gate electrode 5 caused (mainly between the gate electrode 5 and the source/drain region 12) due to the insulating offset sidewall 6 can be reduced. Also, in this case, the insulating offset sidewall 6 is preferably formed, so as to attain a lower dielectric constant than the high dielectric constant gate insulating film 4B, by using the same material as that used for the high dielectric constant gate insulating film 4B with its composition ratios changed. Thus, the dielectric constant of the insulating offset sidewall 6 can be easily made lower than that of the high dielectric constant gate insulating film 4B while suppressing the lowering of the dielectric constant and the insulating property of the high dielectric constant gate insulating film 4B, namely, while keeping high the dielectric constant of the high dielectric constant gate insulating film 4B below the end of the gate electrode 5 so as to minimize the lowering of the gate/drain overlap effect.

Also in this modification, the insulating sidewall 7 may or may not have a high dielectric constant. Furthermore, in this modification, the insulating sidewall 7 may have a multilayered structure shown in, for example, FIG. 7A or 7B (see Embodiment 2).

Furthermore, the gate electrode 5 is preferably a full silicide gate electrode or a metal gate electrode also in this modification. Thus, the degree of integration, the performance and the operation speed of the semiconductor device can be definitely improved.

### Modification 3 of Embodiment 2

A semiconductor device according to Modification 3 of Embodiment 2 of the invention will now be described with reference to the accompanying drawing. FIG. 10 is a cross-sectional view for showing the structure of the semiconductor device (specifically, a double sidewall type MISFET) according to Modification 3 of Embodiment 2. It is noted that this modification is obtained by further modifying Modification 2 of Embodiment 2.

This modification is different from Modification 2 of Embodiment 2 in a notch 20 provided in a side end portion of the high dielectric constant gate insulating film 4B and formed by removing a part of the high dielectric constant gate insulating film 4B below the insulating offset sidewall 6 as shown in FIG. 10.

According to this modification, not only the same effects as those attained in Modification 2 of Embodiment 2 can be attained but also the harmful influence on the circuit speed derived from the increase of the capacitance between the gate electrode 5 and the source/drain region 12 can be further suppressed.

Needless to say, the effects similar to those of this modification can be attained by additionally providing the aforementioned characteristic of this modification to Embodiment 2 or Modification 1 thereof.

### Embodiment 3

A semiconductor device according to Embodiment 3 of the invention will now be described with reference to the accompanying drawing. Although the single sidewall type MISFET is described in Embodiment 1, a double sidewall type MISFET (see Non-patent document 3 mentioned above) in which overlap between a gate electrode and an extension region can be easily optimized is described in Embodiment 3 similarly to Embodiment 2.

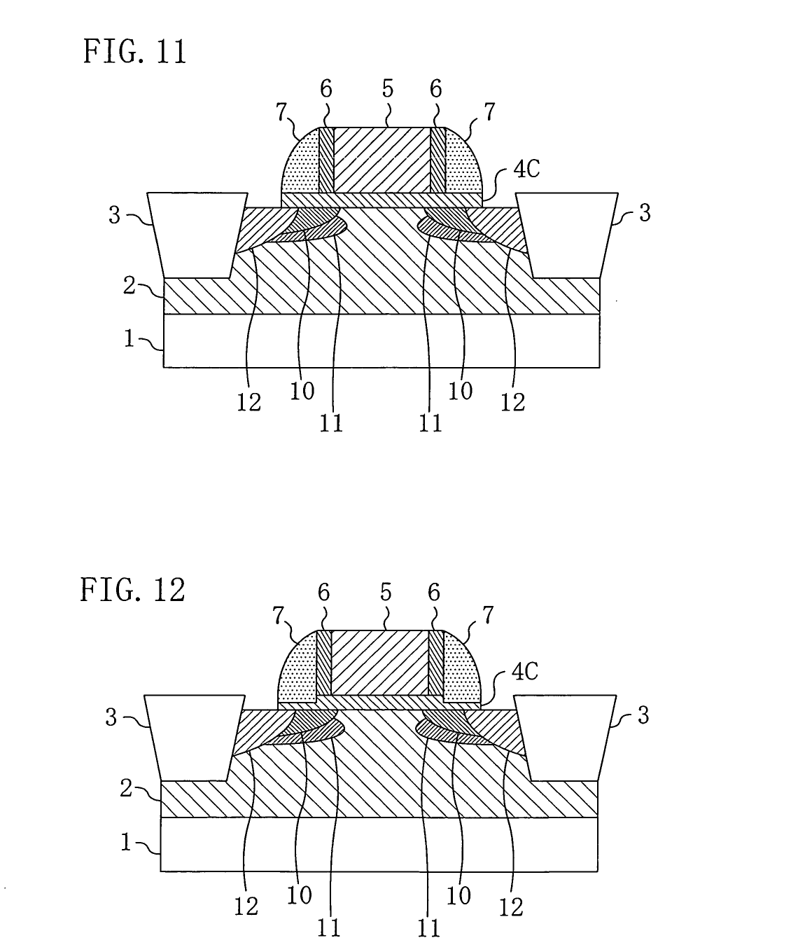

FIG. 11 is a cross-sectional view for showing the structure of the semiconductor device of Embodiment 3. As shown in FIG. 11, a gate electrode 5 is formed on a portion, surrounded with an STI 3, of a well 2 corresponding to an active region of a substrate 1 of, for example, silicon with a high dielectric constant gate insulating film 4C of, for example, HfO₂, HfSiO₂, HfSiON or HfAlOₓ sandwiched therebetween. An insulating sidewall 7 is formed above the side face of the gate electrode 5 with an insulating offset sidewall 6 having a high dielectric constant sandwiched therebetween. An extension region 10 is formed in a portion of the well 2 disposed below the insulating offset sidewall 6 and the insulating sidewall 7, and a pocket region 11 is formed in a portion of the well 2 disposed below the extension region 10. A source/drain region 12 is formed in a portion of the well 2 disposed away from the gate electrode 5 beyond the extension region 10 and the pocket region 11.

As a first characteristic of this embodiment, the insulating offset sidewall 6 is made of a high dielectric constant insulating film of, for example, HfO₂, HfSiO₂, HfSiON or HfAlOₓ.

As a second characteristic of this embodiment, the high dielectric constant gate insulating film 4C is formed so as to continuously extend from under the gate electrode 5 to under the insulating sidewall 7. In other words, differently from Modification 1 of Embodiment 2, the high dielectric constant gate insulating film 4C remains not only below the gate electrode 5 and the insulating offset sidewall 6 but also below the insulating sidewall 7 in this embodiment.

According to this embodiment, since the insulating offset sidewall 6 formed on the side face of the gate electrode 5 has a high dielectric constant, it is possible to avoid the conventional problem that the composition of a side end portion of the high dielectric constant gate insulating film 4C approximates to SiO₂, which is caused through the contact between the side end portion of the high dielectric constant insulating film 4C and a conventional insulating film during the formation of an offset sidewall made of the conventional insulating film such as a silicon oxide film. Therefore, the lowering of the dielectric constant and the insulating property of the high dielectric constant gate insulating film 4C otherwise caused at the end of the gate electrode 5 can be prevented, so as to prevent the degradation of the device characteristics and the reliability of the gate insulating film.

Furthermore, in this embodiment, since the insulating offset sidewall 6 formed on the side face of the gate electrode 5 has a high dielectric constant and the high dielectric constant gate insulating film 4C is formed so as to continuously extend from under the gate electrode 5 to under the insulating sidewall 7, the capacitive coupling between the gate electrode 5 and the extension region 10 is increased in the vicinity of the end of the gate electrode 5, and hence, a high gate/drain overlap effect can be attained. Therefore, the device characteristics and the hot charier resistance can be improved (see, for example, Non-patent document 2 mentioned above).

Moreover, in this embodiment, since the high dielectric constant gate insulating film 4C is formed so as to continuously extend from under the gate electrode 5 to under the insulating sidewall 7, the continuity of the high dielectric constant gate insulating film 4C is kept at the end of the gate electrode 5, and therefore, the side end portion of the high dielectric constant gate insulating film 4C is never in direct contact with a conventional sidewall film such as a silicon oxide film at the end of the gate electrode 5. For example, even when the width of the insulating offset sidewall 6 is very small, the side end portion of the high dielectric constant gate insulating film 4C never comes into contact with the insulating sidewall 7. Accordingly, the lowering of the dielectric constant and the insulating property of the high dielectric constant gate insulating film 4C otherwise caused at the end of the gate electrode 5 can be more definitely suppressed, and therefore, the degradation of the device characteristics and the reliability of the gate insulating film can be more definitely prevented.

In this embodiment, the dielectric constant of the insulating offset sidewall 6 is preferably lower than that of the high dielectric constant gate insulating film 4C. Thus, the parasitic capacitance of the gate electrode 5 caused (mainly between the gate electrode 5 and the source/drain region 12) due to the insulating offset sidewall 6 can be reduced. Also, in this case, the insulating offset sidewall 6 is preferably formed, so as to attain a lower dielectric constant than the high dielectric constant gate insulating film 4C, by using the same material as that used for the high dielectric constant gate insulating film 4C with its composition ratios changed. Thus, the dielectric constant of the insulating offset sidewall 6 can be easily made lower than that of the high dielectric constant gate insulating film 4C while suppressing the lowering of the dielectric constant and the insulating property of the high dielectric constant gate insulating film 4C.

In this embodiment, the insulating sidewall 7 may or may not have a high dielectric constant. Although the insulating sidewall 7 of this embodiment has a single-layered structure, the insulating sidewall 7 may have a multilayered structure including two or more layers as shown in, for example, FIGS. 7A and 7B instead (see Embodiment 2).

Furthermore, in this embodiment, the gate electrode 5 is preferably a full silicide gate electrode or a metal gate electrode. Thus, the degree of integration, the performance and the operation speed of the semiconductor device can be definitely improved.

### Modification of Embodiment 3

A semiconductor device according to modifications of Embodiment 3 will now be described with reference to the accompanying drawings. FIG. 12 is a cross-sectional view for showing the structure of a semiconductor device (specifically, a double sidewall type MISFET) according to a modification of Embodiment 3.

This modification is different from Embodiment 3 in the high dielectric constant gate insulating film 4C having a smaller thickness below the insulating sidewall 7 than below the gate electrode 5 and the insulating offset sidewall 6. Specifically, in this modification, the high dielectric constant gate insulating film 4C has an equivalent thickness below the insulating offset sidewall 6 and below the gate electrode 5 and has a smaller thickness below the insulating sidewall 7 than below the gate electrode 5. In other words, the high dielectric constant gate insulating film 4C is formed in a convex shape in this modification.

According to this modification, the following effects can be attained in addition to the effects attained in Embodiment 3: Since the high dielectric constant gate insulating film 4C remains below the insulating sidewall 7 in Embodiment 3 in the same manner as in Modification 1 of Embodiment 1 (see FIG. 3), the parasitic capacitance caused between the gate electrode 5 and the source/drain region 12 may be increased. On the contrary, in this modification, the high dielectric constant gate insulating film 4C has a smaller thickness below the insulating sidewall 7 than below the gate electrode 5 and the insulating offset sidewall 6, and therefore, the increase of the parasitic capacitance and its harmful influence on the circuit speed can be suppressed.

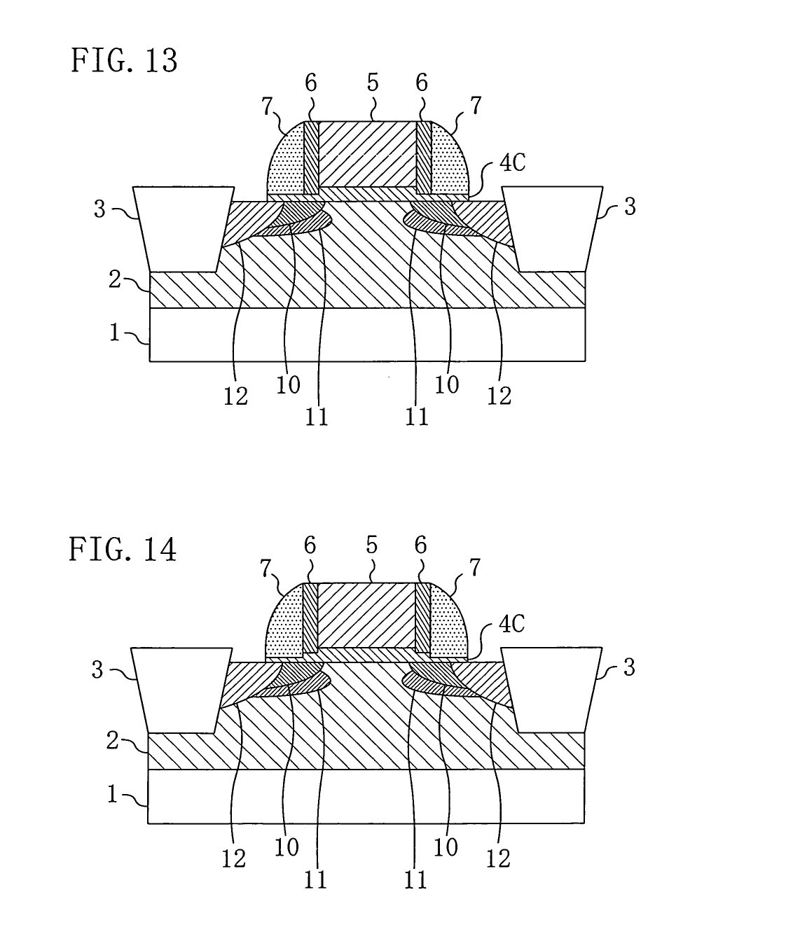

In this modification, in order to further suppress the increase of the parasitic capacitance and its harmful influence on the circuit speed, the thickness of the high dielectric constant gate insulating film 4C may be smaller below the insulating offset sidewall 6 and the insulating sidewall 7 than below the gate electrode 5 as shown in FIG. 13. In other words, in the structure shown in FIG. 13, the high dielectric constant gate insulating film 4C has a smaller thickness below the insulating offset sidewall 6 than below the gate electrode 5 and has an equivalent thickness below the insulating sidewall 7 and below the insulating offset sidewall 6. Furthermore, in the structure shown in FIG. 13, since the high dielectric constant film present on the substrate in the implantation for forming an extension or LDD region has a small thickness, the increase of the implantation acceleration energy can be suppressed. Therefore, a shallow junction can be easily formed in the extension or LDD region, resulting in easily improving the device characteristics.

Alternatively, in this modification, the high dielectric constant gate insulating film 4C may have a smaller thickness below the insulating offset sidewall 6 than below the gate electrode 5 and a smaller thickness below the insulating sidewall 7 than below the insulating offset sidewall 6 as shown in FIG. 14. In other words, the high dielectric constant gate insulating film 4C may be in a double convex shape. Thus, not only the same effects as those attained by the structure shown in FIG. 13 can be attained but also the increase of the parasitic capacitance and its harmful influence on the circuit speed can be further suppressed.

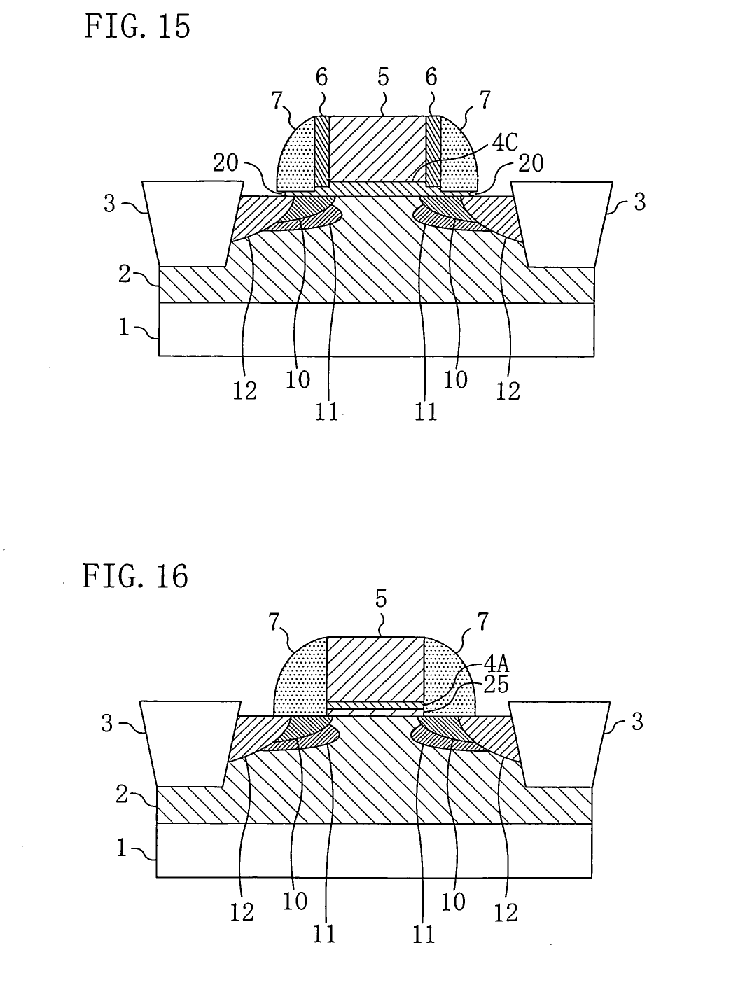

Further alternatively, in the structure of the modification shown in, for example, FIG. 14, a notch 20 may be provided in a side end portion of the high dielectric constant gate insulating film 4C by removing a part of the high dielectric constant gate insulating film 4C below the insulating sidewall 7 as shown in FIG. 15. Thus, not only the same effects as those attained by the structure shown in FIG. 14 can be attained but also the harmful influence on the circuit speed derived from the increase of the capacitance between the gate electrode 5 and the source/drain region 12 can be further suppressed. Also, the same effects can be attained when the notch 20 is provided to the structure of Embodiment 3 shown in FIG. 11 or the structure of the modification shown in FIG. 12 or 13.

In this modification, the dielectric constant of the insulating offset sidewall 6 is preferably lower than that of the high dielectric constant gate insulating film 4C. Thus, the parasitic capacitance of the gate electrode 5 caused (mainly between the gate electrode 5 and the source/drain region 12) due to the insulating offset sidewall 6 can be reduced. Also, in this case, the insulating offset sidewall 6 is preferably formed, so as to attain a lower dielectric constant than the high dielectric constant gate insulating film 4C, by using the same material as that used for the high dielectric constant gate insulating film 4C with its composition ratios changed. Thus, the dielectric constant of the insulating offset sidewall 6 can be easily made lower than that of the high dielectric constant gate insulating film 4C while suppressing the lowering of the dielectric constant and the insulating property of the high dielectric constant gate insulating film 4C, namely, while keeping high the dielectric constant of the high dielectric constant gate insulating film 4C below the end of the gate electrode 5 so as to minimize the lowering of the gate/drain overlap effect.

In this modification, the insulating sidewall 7 may or may not have a high dielectric constant. Also in this modification, the insulating sidewall 7 may have a multilayered structure as shown in, for example, FIGS. 7A and 7B instead (see Embodiment 2).

Furthermore, in this modification, the gate electrode 5 is preferably a full silicide gate electrode or a metal gate electrode. Thus, the degree of integration, the performance and the operation speed of the semiconductor device can be definitely improved.

### Embodiment 4

A semiconductor device according to Embodiment 4 of the invention will now be described with reference to the accompanying drawing. FIG. 16 is a cross-sectional view for showing the structure of the semiconductor device (specifically, a single sidewall type MISFET) according to Embodiment 4.

This embodiment is different from Embodiment 1 (shown in FIG. 1) in a buffer insulating film 25 made of, for example, a silicon oxide film or a silicon nitride film provided between the substrate 1 and the high dielectric constant gate insulating film 4A as shown in FIG. 16.

According to this embodiment, in addition to the effects attained in Embodiment 1, an effect to normally keep the interface between the substrate and the gate insulating film can be attained. Specifically, since the high dielectric constant gate insulating film 4A is formed above the substrate 1 with the buffer insulating film 25 sandwiched therebetween, degradation of the interface between the substrate and the gate insulating film can be prevented as compared with the case where the high dielectric constant gate insulating film 4A is formed directly on the substrate 1.

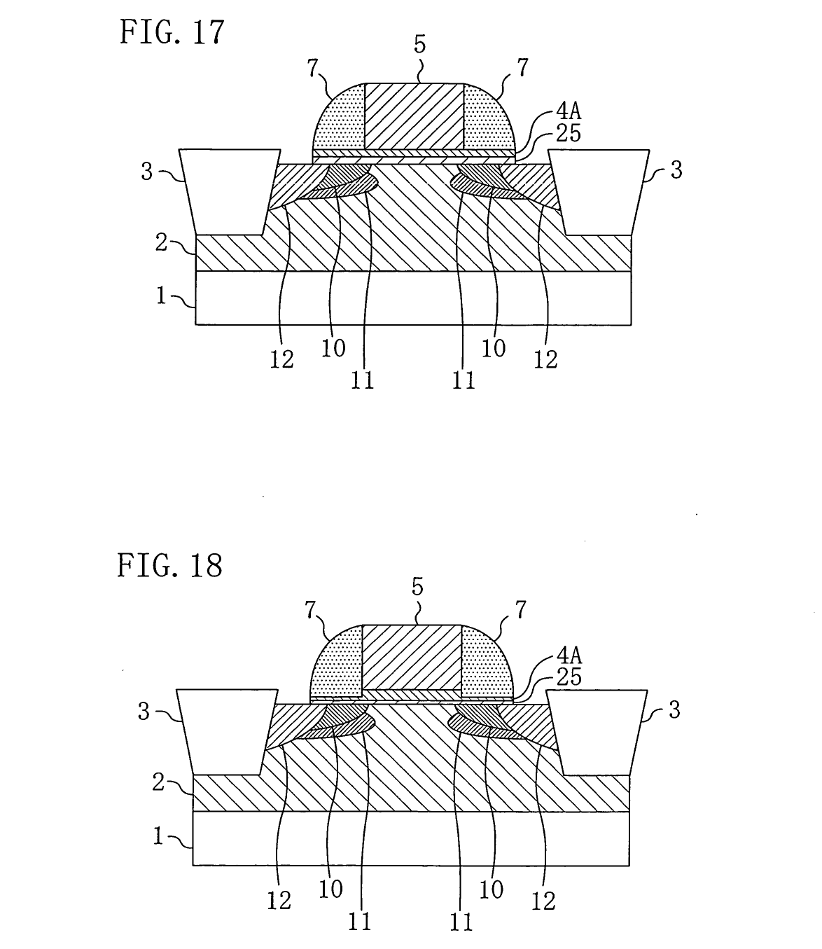

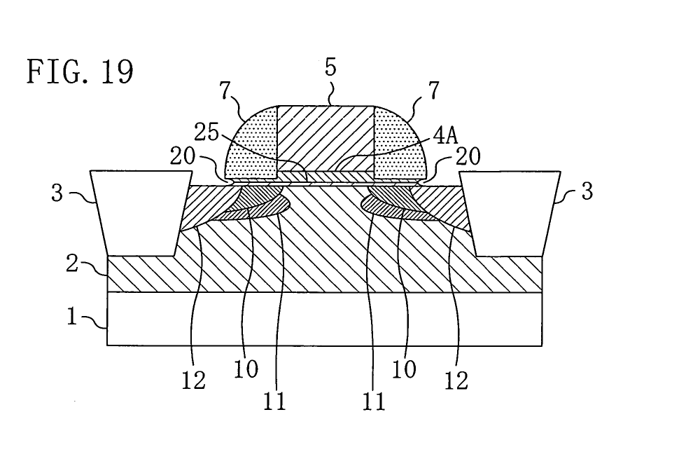

In this embodiment, the buffer insulating film 25 is provided between the high dielectric constant gate insulating film 4A and the substrate 1 in the structure of Embodiment 1 shown in FIG. 1. The same effect as that attained in this embodiment can be attained even when the buffer insulating film 25 is provided as shown in FIG. 17 between the high dielectric constant gate insulating film 4A and the substrate 1 in the structure of Modification 1 of Embodiment 1 shown in FIG. 3. Alternatively, the same effect as that attained in this embodiment can be attained even when the buffer insulating film 25 is provided as shown in FIG. 18 between the high dielectric constant gate insulating film 4A and the substrate 1 in the structure of Modification 2 of Embodiment 1 shown in FIG. 4. Alternatively, the same effect as that attained in this embodiment can be attained even when the buffer insulating film 25 is provided as shown in FIG. 19 between the high dielectric constant gate insulating film 4A and the substrate 1 in the structure of Modification 3 of Embodiment 1 shown in FIG. 5. Alternatively, the same effect as that attained in this embodiment can be attained even when the buffer insulating film is provided between the high dielectric constant gate insulating film 4B and the substrate 1 in any of the structures of Embodiment 2 and its modifications shown in FIGS. 6, 8, 9 and 10. Alternatively, the same effect as that attained in this embodiment can be attained even when the buffer insulating film is provided between the high dielectric constant gate insulating film 4C and the substrate 1 in any of the structures of Embodiment 3 and its modifications shown in FIGS. 11, 12, 13, 14 and 15. Further alternatively, the buffer insulating film may be provided between the gate electrode 5 and the high dielectric constant gate insulating film 4A, 4B or 4C instead of between the high dielectric constant gate insulating film 4A, 4B or 4C and the substrate 1. In this case, the interface between the gate electrode and the gate insulating film can be prevented from degrading as compared with the case where the gate electrode 5 is formed directly on the high dielectric constant gate insulating film 4A, 4B or 4C. Alternatively, the buffer insulating films may be provided between the high dielectric constant gate insulating film 4A, 4B or 4C and the substrate 1 and between the gate electrode 5 and the high dielectric constant gate insulating film 4A, 4B or 4C. In this case, both of the interface between the substrate and the gate insulating film and the interface between the gate insulating film and the gate electrode can be prevented from degrading.

### Embodiment 5

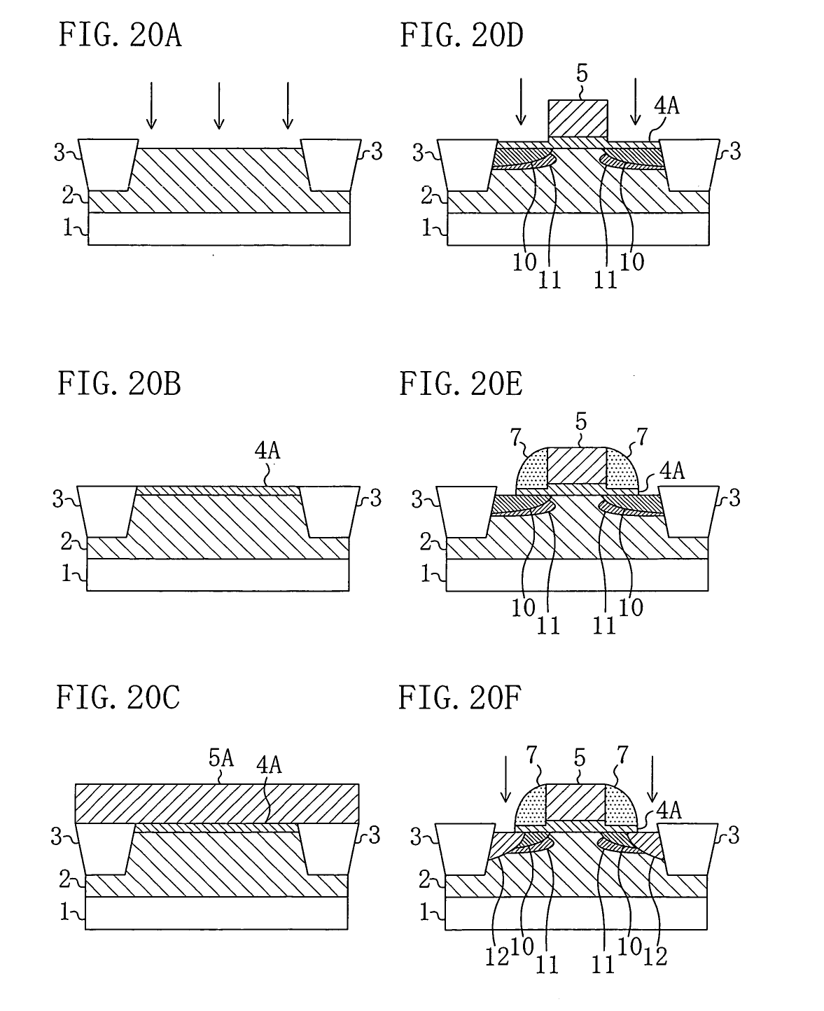

A method for fabricating a semiconductor device according to Embodiment 5 of the invention will now be described with reference to the accompanying drawings by exemplifying a fabrication method for an N-channel MISFET. FIGS. 20A through 20F are cross-sectional views for showing procedures in the method for fabricating a semiconductor device of Embodiment 5.

First, as shown in FIG. 20A, after an STI 3 corresponding to an isolation region is selectively formed on a substrate 1 of, for example, silicon, ions of, for example, B (boron) are implanted into the substrate 1 at implantation energy of 300 keV and a dose of 1×10¹³ cm⁻². Thus, a well 2 corresponding to an active region is formed. Subsequently, ion implantation for forming a punch through stopper (using ions of B at implantation energy of 150 keV and a dose of 1×10¹³ cm⁻²) and ion implantation for forming a channel (using ions of B at implantation energy of 20 keV and a dose of 5×10¹² cm⁻²) are performed.

Next, as shown in FIG. 20B, after a buffer insulating film made of, for example, a silicon oxide film (not shown) with a thickness of approximately 0.5 nm is formed on a portion of the well 2 surrounded with the STI 3, a high dielectric constant gate insulating film 4A made of, for example, a HfSiON film with a thickness of approximately 4 nm (corresponding to a thickness of approximately 1 nm when converted as an oxide film) is deposited.

Then, as shown in FIG. 20C, a gate electrode material film 5A made of, for example, TaN or the like with a thickness of approximately 100 nm is formed on the high dielectric constant gate insulating film 4A.

Next, after forming, on the gate electrode material film 5A, a resist pattern (not shown) for covering a gate electrode forming region, the gate electrode material film 5A is etched by using the resist pattern as a mask, thereby forming a gate electrode 5 as shown in FIG. 20D. Thereafter, a portion of the high dielectric constant gate insulating film 4A disposed outside the gate electrode 5 is further removed by a thickness of approximately 2 nm through selective etching. Thus, the portion of the high dielectric constant gate insulating film 4A disposed outside the gate electrode 5 can be thinned to a thickness of approximately 2 nm.

Subsequently, by using the gate electrode 5 as a mask, for example, As (arsenic) is ion implanted into the substrate 1 at implantation energy of 2 keV and a dose of 1×10¹⁵ cm⁻², thereby forming an extension region 10. Thereafter, by using the gate electrode 5 as a mask, for example, B is ion implanted into the substrate 1 at implantation energy of 10 keV and a dose of 3×10¹³ cm⁻², thereby forming a pocket region 11. It is noted that the extension region 10 may be formed after forming the pocket region 11 in this embodiment.

Next, after depositing a high dielectric constant insulating film of, for example, a HfSiON film with a thickness of approximately 50 nm over the whole top surface of the substrate 1, the high dielectric constant insulating film is etched back, so as to form an insulating sidewall 7 with a high dielectric constant on the side face of the gate electrode 5 as shown in FIG. 20E.

Then, by using the gate electrode 5 and the insulating sidewall 7 as a mask, for example, As is ion implanted into the substrate 1 at implantation energy of 10 keV and a dose of 5×10¹⁵ cm⁻², and then, SPIKE RTA (rapid thermal annealing) is performed at a temperature of approximately 1050° C., thereby activating the implanted impurity. Thus, a source/drain region 12 is formed as shown in FIG. 20F.

In the fabrication method of this embodiment described above, the MISFET structure of Modification 2 of Embodiment 1 (shown in FIG. 4) can be comparatively easily realized.

Specifically, according to this embodiment, since the insulating sidewall 7 formed on the side face of the gate electrode 5 has a high dielectric constant, it is possible to avoid the conventional problem that the composition of a side end portion of the high dielectric constant gate insulating film 4A approximates to SiO₂, which is caused through direct contact between the side end portion of the high dielectric constant gate insulating film 4A and a conventional insulating film during the formation of a sidewall made of the conventional insulating film such as a silicon oxide film. Therefore, the lowering of the dielectric constant and the insulating property of the high dielectric constant gate insulating film 4A otherwise caused at the end of the gate electrode 5 can be prevented, so as to prevent the degradation of the device characteristics and the reliability of the gate insulating film.

Moreover, according to this embodiment, since the insulating sidewall 7 formed on the side face of the gate electrode 5 has a high dielectric constant and the high dielectric constant gate insulating film 4A is formed so as to continuously extend from under the gate electrode 5 to under the insulating sidewall 7, the capacitive coupling between the gate electrode 5 and the extension region 10 is increased in the vicinity of the end of the gate electrode 5, resulting in attaining a high gate/drain overlap effect. Accordingly, the device characteristics and the hot carrier resistance can be improved (see, for example, Non-patent document 2 mentioned above).

Furthermore, according to this embodiment, since the high dielectric constant gate insulating film 4A is formed so as to continuously extend from under the gate electrode 5 to under the insulating sidewall 7, the continuity of the high dielectric constant gate insulating film 4A is kept at the end of the gate electrode 5, and therefore, the side end portion of the high dielectric constant gate insulating film 4A is never in direct contact with a conventional sidewall film such as a silicon oxide film at the end of the gate electrode 5. Accordingly, the lowering of the dielectric constant and the insulating property of the high dielectric constant gate insulating film 4A otherwise caused at the end of the gate electrode 5 can be more definitely suppressed, and therefore, the degradation of the device characteristics and the reliability of the gate insulating film can be more definitely prevented.

Furthermore, according to this embodiment, since the high dielectric constant gate insulating film 4A has a smaller thickness below the insulating sidewall 7 than below the gate electrode 5, the increase of gate/drain capacitance can be suppressed so as to reduce the harmful influence on the circuit speed.

Since the high dielectric constant gate insulating film 4A includes a heavy metal, the Rp (projection range) of implanted ions passing through the high dielectric constant gate insulating film 4A tends to be small. Therefore, in the procedure for forming the extension region 10 or the pocket region 11 shown in FIG. 20D, the acceleration energy should be large in implanting the ions into the portion of the substrate 1 disposed outside the gate electrode 5 and covered with the high dielectric constant gate insulating film 4A. In this embodiment, however, the high dielectric constant gate insulating film 4A has a smaller thickness outside the gate electrode 5, the increase of the implantation energy can be suppressed, and hence, a shallow junction can be easily formed in the extension region 10, so as to easily improve the device characteristics.

In this embodiment, after forming the insulating sidewall 7, a portion of the high dielectric constant gate insulating film 4A disposed away from the gate electrode 5 beyond the insulating sidewall 7 may be removed, for example, through wet etching using hydrofluoric acid or selective dry etching. In the case where the wet etching is employed, a notch may be formed in a side end portion of the high dielectric constant gate insulating film 4A by removing a part of the high dielectric constant gate insulating film 4A below a side end portion of the insulating sidewall 7. Thus, the MISFET structure of Modification 3 of Embodiment 1 (shown in FIG. 5) can be easily realized.

Furthermore, in this embodiment, the degree of thinning the high dielectric constant gate insulating film 4A outside the gate electrode 5 is not particularly specified. In the case where the high dielectric constant gate insulating film 4A is made of, for example, a HfSiON film, the high dielectric constant gate insulating film 4A is preferably thinned outside the gate electrode 5 to approximately 2 nm or less (whereas so as not to expose the surface of the substrate 1) in order to suppress the increase of the gate/drain capacitance.

Although the high dielectric constant gate insulating film 4A is allowed to remain outside the gate electrode 5 after forming the gate electrode 5 in the procedure of FIG. 20D in this embodiment, the high dielectric constant gate insulating film 4A may be removed instead. Thus, the MISFET structure of Embodiment 1 (shown in FIG. 1) can be easily realized. In this case, the high dielectric constant gate insulating film 4A may be removed through the wet etching or the selective dry etching. Also, in the case where the wet etching is employed, a notch may be provided in a side end portion of the high dielectric constant gate insulating film 4A by removing a part of the high dielectric constant gate insulating film 4A below a side end portion of the gate electrode 5.

Furthermore, although the high dielectric constant gate insulating film 4A is thinned outside the gate electrode 5 after forming the gate electrode 5 in the procedure of FIG. 20D in this embodiment, the high dielectric constant gate insulating film 4A may not be thinned instead. Thus, the MISFET structure of Modification 1 of Embodiment 1 (shown in FIG. 3) can be easily realized. In this case, after forming the insulating sidewall 7, a portion of the high dielectric constant gate insulating film 4A disposed away from the gate electrode 5 beyond the insulating sidewall 7 may be removed through, for example, the wet etching using hydrofluoric acid or the selective dry etching. In the case where the wet etching is employed, a notch may be provided in a side end portion of the high dielectric constant gate insulating film 4A by removing a part of the high dielectric constant gate insulating film 4A below a side end portion of the insulating sidewall 7.

In this embodiment, the dielectric constant of the insulating sidewall 7 is preferably lower than that of the high dielectric constant gate insulating film 4A. Thus, the parasitic capacitance of the gate electrode 5 caused (mainly between the gate electrode 5 and the source/drain region 12) due to the insulating sidewall 7 can be reduced. Also, in this case, in the procedure for forming the insulating sidewall 7 shown in FIG. 20E, the insulating sidewall 7 is preferably formed, so as to attain a lower dielectric constant than the high dielectric constant gate insulating film 4A, by using the same material as that used for the high dielectric constant gate insulating film 4A with its composition ratios changed. Thus, the dielectric constant of the insulating sidewall 7 can be easily made lower than that of the high dielectric constant gate insulating film 4A while suppressing the lowering of the dielectric constant and the insulating property of the high dielectric constant gate insulating film 4A. Specifically, in the case where the high dielectric constant gate insulating film 4A is made of, for example, a HfSiON film, the Hf concentration in the HfSiON film used as the high dielectric constant gate insulating film 4A is set to approximately 50 at % and the Hf concentration in the insulating sidewall 7 made of a similar HfSiON film is set to approximately 30 at %. Thus, the dielectric constant of the insulating sidewall 7 can be made lower than that of the high dielectric constant gate insulating film 4A.

Although the insulating sidewall 7 has a single-layered structure in this embodiment, the insulating sidewall 7 may have a multilayered structure including two or more layers shown in, for example, FIG. 2A or 2B (see Embodiment 1).

Furthermore, the gate electrode 5 is preferably a full silicide gate electrode or a metal gate electrode in this embodiment. Thus, the degree of integration, the performance and the operation speed of the semiconductor device can be definitely improved. For example, in the procedure for forming the gate electrode 5 shown in FIG. 20D, a protection film for covering the top face of the gate electrode 5 is formed, and the surface of the source/drain region 12 is silicided after forming the source/drain region 12 in the procedure of FIG. 20F. Then, after removing the protection film, the gate electrode 5 may be fully silicided. Thus, a semiconductor device having a full silicide gate electrode can be easily realized.

### Embodiment 6

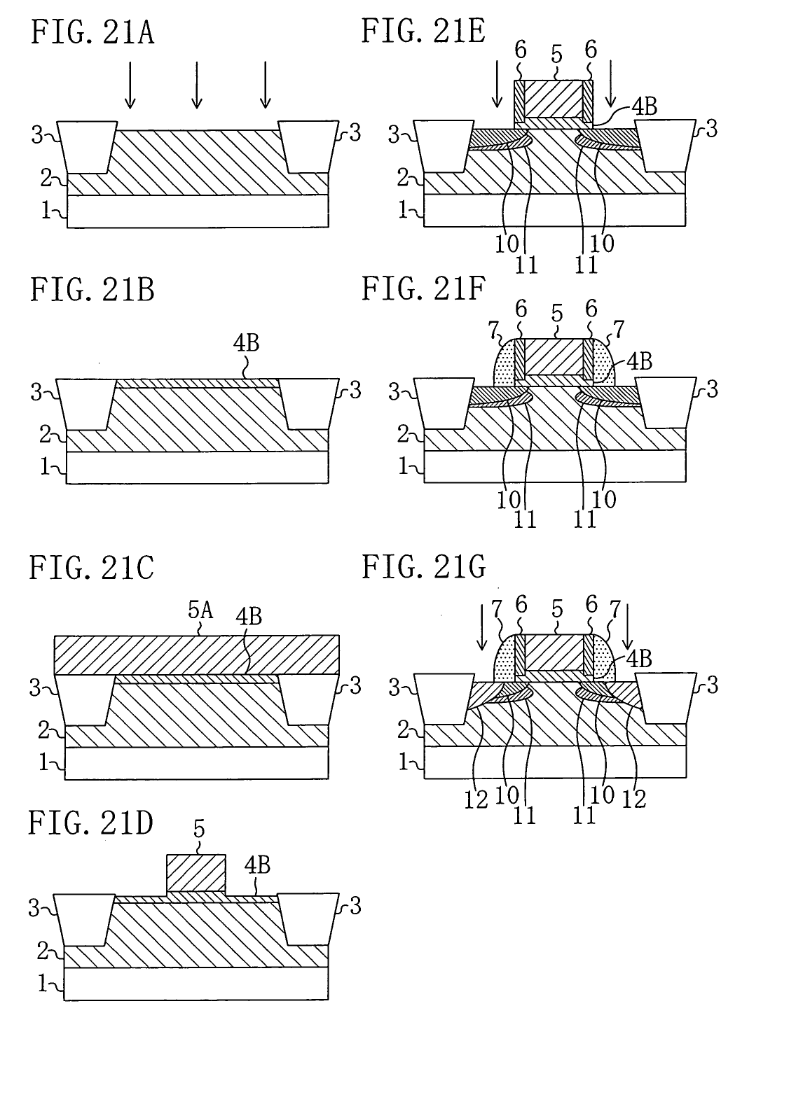

A method for fabricating a semiconductor device according to Embodiment 6 of the invention will now be described with reference to the accompanying drawings by exemplifying a fabrication method for an N-channel MISFET. FIGS. 21A through 21G are cross-sectional views for showing procedures in the method for fabricating a semiconductor device of Embodiment 6.

First, as shown in FIG. 21A, after an STI 3 corresponding to an isolation region is selectively formed on a substrate 1 of, for example, silicon, ions of, for example, B are implanted into the substrate 1 at implantation energy of 300 keV and a dose of 1×10¹³ cm⁻². Thus, a well 2 corresponding to an active region is formed. Subsequently, ion implantation for forming a punch through stopper (using ions of B at implantation energy of 150 keV and a dose of 1×10¹³ cm⁻²) and ion implantation for forming a channel (using ions of B at implantation energy of 20 keV and a dose of 5×10¹² cm⁻²) are performed.

Next, as shown in FIG. 21B, after a buffer insulating film made of, for example, a silicon oxide film (not shown) with a thickness of approximately 0.5 nm is formed on a portion of the well 2 surrounded with the STI 3, a high dielectric constant gate insulating film 4B made of, for example, a HfSiON film with a thickness of approximately 4 nm (corresponding to a thickness of approximately 1 nm when converted as an oxide film) is deposited.

Then, as shown in FIG. 21C, a gate electrode material film 5A made of, for example, TaN or the like with a thickness of approximately 100 nm is formed on the high dielectric constant gate insulating film 4B.

Next, after forming, on the gate electrode material film 5A, a resist pattern (not shown) for covering a gate electrode forming region, the gate electrode material film 5A is etched by using the resist pattern as a mask, thereby forming a gate electrode 5 as shown in FIG. 21D. Thereafter, a portion of the high dielectric constant gate insulating film 4B disposed outside the gate electrode 5 is further removed by a thickness of approximately 2 nm through selective etching. Thus, the portion of the high dielectric constant gate insulating film 4B disposed outside the gate electrode 5 can be thinned to a thickness of approximately 2 nm.

Subsequently, after depositing a high dielectric constant insulating film of, for example, a HfSiON film with a thickness of approximately 10 nm over the whole top surface of the substrate 1, the high dielectric constant insulating film is etched back, so as to form an insulating offset sidewall 6 on the side face of the gate electrode 5 as shown in FIG. 21E. Thereafter, a portion of the high dielectric constant gate insulating film 4B disposed away from the gate electrode 5 beyond the insulating offset sidewall 6 is removed through, for example, the wet etching using hydrofluoric acid or the selective dry etching. Subsequently, by using the gate electrode 5 and the insulating offset sidewall 6 as a mask, for example, As is ion implanted into the substrate 1 at implantation energy of 2 keV and a dose of 1×10¹⁵ cm⁻², thereby forming an extension region 10. Then, by using the gate electrode 5 and the insulating offset sidewall 6 as a mask, for example, B is ion implanted into the substrate 1 at implantation energy of 10 keV and a dose of 3×10¹³ cm⁻², thereby forming a pocket region 11. It is noted that the extension region 10 may be formed after forming the pocket region 11 in this embodiment.

Next, after depositing an insulating film with a thickness of, for example, approximately 50 nm over the whole surface of the substrate 1, the insulating film is etched back, so as to form an insulating sidewall 7 above the side face of the gate electrode 5 with the insulating offset sidewall 6 sandwiched therebetween as shown in FIG. 21F.

Then, by using the gate electrode 5, the insulating offset sidewall 6 and the insulating sidewall 7 as a mask, for example, As is ion implanted into the substrate 1 at implantation energy of 10 keV and a dose of 5×10¹⁵ cm⁻², and thereafter, the SPIKE RTA is performed at a temperature of, for example, 1050° C., thereby activating the implanted impurity. Thus, a source/drain region 12 is formed as shown in FIG. 21G.

In the fabrication method of this embodiment described above, the MISFET structure of Modification 2 of Embodiment 2 (shown in FIG. 9) can be comparatively easily realized.

Specifically, according to this embodiment, since the insulating offset sidewall 6 formed on the side face of the gate electrode 5 has a high dielectric constant, it is possible to avoid the conventional problem that the composition of a side end portion of the high dielectric constant gate insulating film 4B approximates to SiO₂, which is caused through direct contact between the side end portion of the high dielectric constant gate insulating film 4B and a conventional insulating film during the formation of an offset sidewall made of the conventional insulating film such as a silicon oxide film. Therefore, the lowering of the dielectric constant and the insulating property of the high dielectric constant gate insulating film 4B otherwise caused at the end of the gate electrode 5 can be prevented, so as to prevent the degradation of the device characteristics and the reliability of the gate insulating film.

Moreover, according to this embodiment, since the insulating offset sidewall 6 formed on the side face of the gate electrode 5 has a high dielectric constant and the high dielectric constant gate insulating film 4B is formed so as to continuously extend from under the gate electrode 5 to under the insulating offset sidewall 6, the capacitive coupling between the gate electrode 5 and the extension region 10 is increased in the vicinity of the end of the gate electrode 5, resulting in attaining a high gate/drain overlap effect. Accordingly, the device characteristics and the hot carrier resistance can be improved (see, for example, Non-patent document 2 mentioned above).

Furthermore, according to this embodiment, since the high dielectric constant gate insulating film 4B is formed so as to continuously extend from under the gate electrode 5 to under the insulating offset sidewall 6, the continuity of the high dielectric constant gate insulating film 4B is kept at the end of the gate electrode 5, and therefore, the side end portion of the high dielectric constant gate insulating film 4B is never in direct contact with a conventional sidewall film such as a silicon oxide film at the end of the gate electrode 5. Accordingly, the lowering of the dielectric constant and the insulating property of the high dielectric constant gate insulating film 4B otherwise caused at the end of the gate electrode 5 can be more definitely suppressed, and therefore, the degradation of the device characteristics and the reliability of the gate insulating film can be more definitely prevented.

Furthermore, according to this embodiment, since the high dielectric constant gate insulating film 4B has a smaller thickness below the insulating offset sidewall 6 than below the gate electrode 5, the increase of gate/drain capacitance can be suppressed so as to reduce the harmful influence on the circuit speed. Moreover, since the high dielectric constant film present on the substrate in performing the implantation for forming an extension region and an LDD region has a small thickness, the increase of the implantation acceleration energy can be suppressed. Therefore, a shallow junction can be easily formed in the extension region and the LDD region, and hence, the device characteristics can be easily improved.

In this embodiment, after forming the insulating offset sidewall 6, a portion of the high dielectric constant gate insulating film 4B disposed away from the gate electrode 5 beyond the insulating offset sidewall 6 may be removed through, for example, the wet etching using hydrofluoric acid or the selective dry etching. In the case where the wet etching is employed, a notch may be formed in a side end portion of the high dielectric constant gate insulating film 4B by removing a part of the high dielectric constant gate insulating film 4B below a side end portion of the insulating offset sidewall 6. Thus, the MISFET structure of Modification 3 of Embodiment 2 (shown in FIG. 10) can be easily realized.

Furthermore, in this embodiment, the degree of thinning the high dielectric constant gate insulating film 4B outside the gate electrode 5 is not particularly specified. In the case where the high dielectric constant gate insulating film 4B is made of, for example, a HfSiON film, the high dielectric constant gate insulating film 4B is preferably thinned outside the gate electrode 5 to approximately 2 nm or less (whereas so as not to expose the surface of the substrate 1) in order to suppress the increase of the gate/drain capacitance.

In this embodiment, the dielectric constant of the insulating offset sidewall 6 is preferably lower than that of the high dielectric constant gate insulating film 4B. Thus, the parasitic capacitance of the gate electrode 5 caused (mainly between the gate electrode 5 and the source/drain region 12) due to the insulating offset sidewall 6 can be reduced. Also, in this case, in the procedure for forming the insulating offset sidewall 6 shown in FIG. 21E, the insulating offset sidewall 6 is preferably formed, so as to attain a lower dielectric constant than the high dielectric constant gate insulating film 4B, by using the same material as that used for the high dielectric constant gate insulating film 4B with its composition ratios changed. Thus, the dielectric constant of the insulating offset sidewall 6 can be easily made lower than that of the high dielectric constant gate insulating film 4B while suppressing the lowering of the dielectric constant and the insulating property of the high dielectric constant gate insulating film 4B. Specifically, in the case where the high dielectric constant gate insulating film 4B is made of, for example, a HfSiON film, the Hf concentration in the HfSiON film used as the high dielectric constant gate insulating film 4B is set to approximately 50 at % and the Hf concentration in the insulating offset sidewall 6 made of a similar HfSiON film is set to approximately 30 at %. Thus, the dielectric constant of the insulating offset sidewall 6 can be made lower than that of the high dielectric constant gate insulating film 4B.

Furthermore, in this embodiment, the portion of the high dielectric constant gate insulating film 4B disposed away from the gate electrode 5 beyond the insulating offset sidewall 6 is removed after forming the insulating offset sidewall 6, and thereafter, the ion implantation for forming the extension region 10 and the pocket region 11 is performed. Instead, the ion implantation for forming the extension region 10 and the pocket region 11 may be performed with the thinned portion of the high dielectric constant gate insulating film 4B remaining in the portion away from the gate electrode 5 beyond the insulating offset sidewall 6 after forming the insulating offset sidewall 6. Even in this case, since the portion of the high dielectric constant gate insulating film 4B disposed outside the gate electrode 5 has a reduced thickness, the increase of the acceleration energy of the ion implantation can be suppressed. Therefore, a shallow junction can be easily formed in the extension region 10, so as to easily improve the device characteristics. Also in this case, after performing the ion implantation for forming the extension region 10 and the pocket region 11, the portion of the high dielectric constant gate insulating film 4B disposed away from the gate electrode 5 beyond the insulating offset sidewall 6 may be removed, so as to perform ion implantation for forming an extension region and a pocket region of another MISFET of a different channel or a different power system in the same substrate.

Although the high dielectric constant gate insulating film 4B is allowed to remain outside the gate electrode 5 after forming the gate electrode 5 in the procedure of FIG. 21D in this embodiment, the high dielectric constant gate insulating film 4B may be removed instead. Thus, the MISFET structure of Embodiment 2 (shown in FIG. 6) can be easily realized. In this case, the high dielectric constant gate insulating film 4B may be removed through the wet etching or the selective dry etching. Also, in the case where the wet etching is employed, a notch may be provided in a side end portion of the high dielectric constant gate insulating film 4B by removing a part of the high dielectric constant gate insulating film 4B below a side end portion of the gate electrode 5.

Furthermore, although the high dielectric constant gate insulating film 4B is thinned outside the gate electrode 5 after forming the gate electrode 5 in the procedure of FIG. 21D in this embodiment, the high dielectric constant gate insulating film 4B may not be thinned instead. Thus, the MISFET structure of Modification 1 of Embodiment 2 (shown in FIG. 8) can be easily realized. In this case, after forming the insulating offset sidewall 6, the portion of the high dielectric constant gate insulating film 4B disposed away from the gate electrode 5 beyond the insulating offset sidewall 6 may be removed through, for example, the wet etching using hydrofluoric acid or the selective dry etching. In the case where the wet etching is employed, a notch may be provided in a side end portion of the high dielectric constant gate insulating film 4B by removing a part of the high dielectric constant gate insulating film 4B below a side end portion of the insulating offset sidewall 6.

Also in this embodiment, the insulating sidewall 7 may or may not have a high dielectric constant. Furthermore, the insulating sidewall 7 may have a multilayered structure shown in, for example, FIG. 7A or 7B (see Embodiment 2) in this embodiment.

Furthermore, the gate electrode 5 is preferably a full silicide gate electrode or a metal gate electrode in this embodiment. Thus, the degree of integration, the performance and the operation speed of the semiconductor device can be definitely improved. For example, in the procedure for forming the gate electrode 5 shown in FIG. 21D, a protection film for covering the top face of the gate electrode 5 is formed, and the surface of the source/drain region 12 is silicided after forming the source/drain region 12 in the procedure of FIG. 21G. Then, after removing the protection film, the gate electrode 5 may be fully silicided. Thus, a semiconductor device having a full silicide gate electrode can be easily realized.

### Embodiment 7

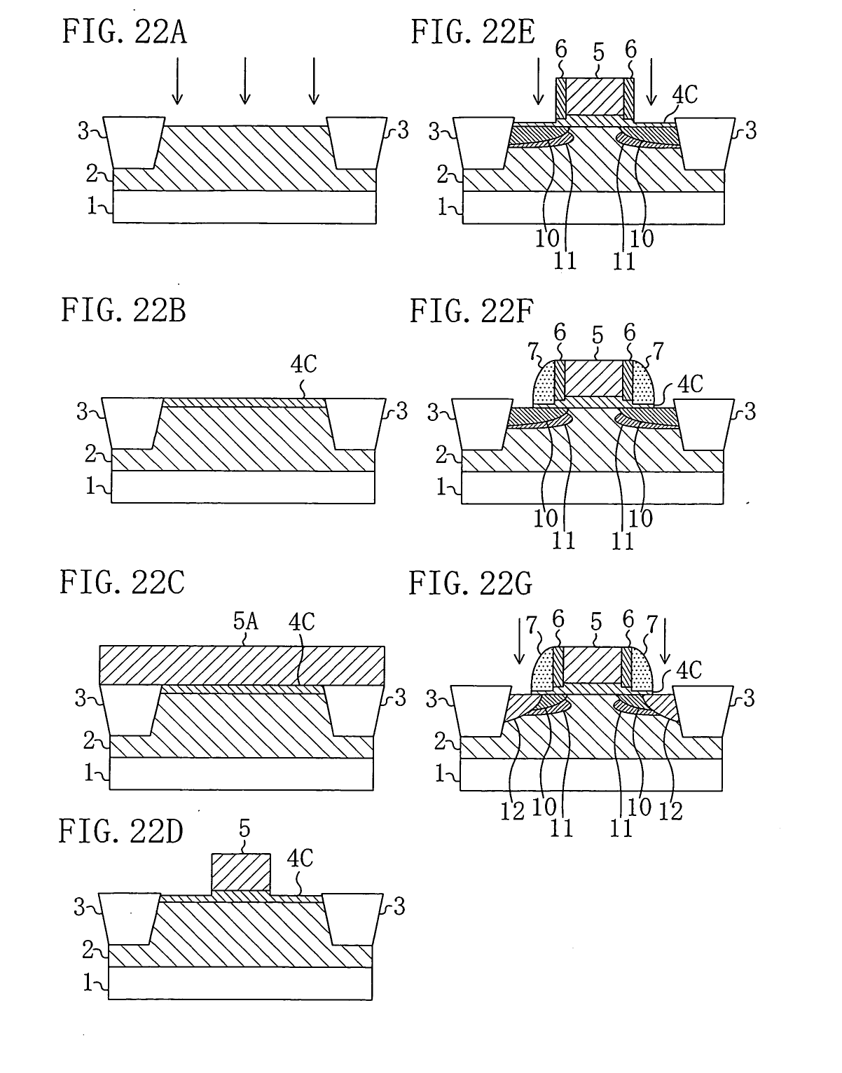

A method for fabricating a semiconductor device according to Embodiment 7 of the invention will now be described with reference to the accompanying drawings by exemplifying a fabrication method for an N-channel MISFET. FIGS. 22A through 22G are cross-sectional views for showing procedures in the method for fabricating a semiconductor device of Embodiment 7.

First, as shown in FIG. 22A, after an STI 3 corresponding to an isolation region is selectively formed on a substrate 1 of, for example, silicon, ions of, for example, B are implanted into the substrate 1 at implantation energy of 300 keV and a dose of 1×10¹³ cm⁻². Thus, a well 2 corresponding to an active region is formed. Subsequently, ion implantation for forming a punch through stopper (using ions of B at implantation energy of 150 keV and a dose of 1×10¹³ cm⁻²) and ion implantation for forming a channel (using ions of B at implantation energy of 20 keV and a dose of 5×10¹² cm⁻²) are performed.

Next, as shown in FIG. 22B, after a buffer insulating film made of, for example, a silicon oxide film (not shown) with a thickness of approximately 0.5 nm is formed on a portion of the well 2 surrounded with the STI 3, a high dielectric constant gate insulating film 4C made of, for example, a HfSiON film with a thickness of approximately 4 nm (corresponding to a thickness of approximately 1 nm when converted as an oxide film) is deposited.

Then, as shown in FIG. 22C, a gate electrode material film 5A made of, for example, TaN or the like with a thickness of approximately 100 nm is formed on the high dielectric constant gate insulating film 4C.

Next, after forming, on the gate electrode material film 5A, a resist pattern (not shown) for covering a gate electrode forming region, the gate electrode material film 5A is etched by using the resist pattern as a mask, thereby forming a gate electrode 5 as shown in FIG. 22D. Thereafter, a portion of the high dielectric constant gate insulating film 4C disposed outside the gate electrode 5 is further removed by a thickness of approximately 2 nm through selective etching. Thus, the portion of the high dielectric constant gate insulating film 4C disposed outside the gate electrode 5 can be thinned to a thickness of approximately 2 nm.

Subsequently, after depositing a high dielectric constant insulating film of, for example, a HfSiON film with a thickness of approximately 5 nm over the whole top surface of the substrate 1, the high dielectric constant insulating film is etched back, so as to form an insulating offset sidewall 6 on the side face of the gate electrode 5 as shown in FIG. 22E. Thereafter, a portion of the high dielectric constant gate insulating film 4C not covered with the gate electrode 5 and the insulating offset sidewall 6 is further removed by a thickness of approximately 1 nm. Thus, the portion of the high dielectric constant gate insulating film 4C disposed away from the gate electrode 5 beyond the insulating offset sidewall 6 can be thinned to a thickness of approximately 1 nm. Thereafter, by using the gate electrode 5 and the insulating offset sidewall 6 as a mask, for example, As is ion implanted into the substrate 1 at implantation energy of 2 keV and a dose of 1×10¹⁵ cm⁻², thereby forming an extension region 10. Then, by using the gate electrode 5 and the insulating offset sidewall 6 as a mask, for example, B is ion implanted into the substrate 1 at implantation energy of 10 keV and a dose of 3×10¹³ cm⁻², thereby forming a pocket region 11. It is noted that the extension region 10 may be formed after forming the pocket region 11 in this embodiment.

Next, after depositing an insulating film with a thickness of, for example, approximately 50 nm over the whole surface of the substrate 1, the insulating film is etched back, so as to form an insulating sidewall 7 above the side face of the gate electrode 5 with the insulating offset sidewall 6 sandwiched therebetween as shown in FIG. 22F.

Then, by using the gate electrode 5, the insulating offset sidewall 6 and the insulating sidewall 7 as a mask, for example, As is ion implanted into the substrate 1 at implantation energy of 10 keV and a dose of 5×10¹⁵ cm⁻², and thereafter, the SPIKE RTA is performed at a temperature of, for example, 1050° C., thereby activating the implanted impurity. Thus, a source/drain region 12 is formed as shown in FIG. 22G.

In the fabrication method of this embodiment described above, the MISFET structure of Embodiment 3 shown in FIG. 14 can be comparatively easily realized.

Specifically, according to this embodiment, since the insulating offset sidewall 6 formed on the side face of the gate electrode 5 has a high dielectric constant, it is possible to avoid the conventional problem that the composition of a side end portion of the high dielectric constant gate insulating film 4C approximates to SiO₂, which is caused through direct contact between the side end portion of the high dielectric constant gate insulating film 4C and a conventional insulating film during the formation of an offset sidewall made of the conventional insulating film such as a silicon oxide film. Therefore, the lowering of the dielectric constant and the insulating property of the high dielectric constant gate insulating film 4C otherwise caused at the end of the gate electrode 5 can be prevented, so as to prevent the degradation of the device characteristics and the reliability of the gate insulating film.

Moreover, according to this embodiment, since the insulating offset sidewall 6 formed on the side face of the gate electrode 5 has a high dielectric constant and the high dielectric constant gate insulating film 4C is formed so as to continuously extend from under the gate electrode 5 to under the insulating sidewall 7, the capacitive coupling between the gate electrode 5 and the extension region 10 is increased in the vicinity of the end of the gate electrode 5, resulting in attaining a high gate/drain overlap effect. Accordingly, the device characteristics and the hot carrier resistance can be improved (see, for example, Non-patent document 2 mentioned above).

Furthermore, according to this embodiment, since the high dielectric constant gate insulating film 4C is formed so as to continuously extend from under the gate electrode 5 to under the insulating sidewall 7, the continuity of the high dielectric constant gate insulating film 4C is kept at the end of the gate electrode 5, and therefore, the side end portion of the high dielectric constant gate insulating film 4C is never in direct contact with a conventional sidewall film such as a silicon oxide film at the end of the gate electrode 5. For example, even when the insulating offset sidewall 6 has a very small width, the side end portion of the high dielectric constant gate insulating film 4C never comes in contact with the insulating sidewall 7. Accordingly, the lowering of the dielectric constant and the insulating property of the high dielectric constant gate insulating film 4C otherwise caused at the end of the gate electrode 5 can be more definitely suppressed, and therefore, the degradation of the device characteristics and the reliability of the gate insulating film can be more definitely prevented.

Furthermore, according to this embodiment, the high dielectric constant gate insulating film 4C has a smaller thickness below the insulating offset sidewall 6 than below the gate electrode 5 and has a smaller thickness below the insulating sidewall 7 than below the insulating offset sidewall 6. Therefore, the increase of the parasitic capacitance between the gate electrode 5 and the source/drain region 12 due to the high dielectric constant gate insulating film 4C remaining below the insulating sidewall 7 and its harmful influence on the circuit speed can be suppressed. Moreover, since the high dielectric constant film present on the substrate in performing the implantation for forming an extension region or an LDD region has a small thickness, the increase of the implantation acceleration energy can be suppressed. Therefore, a shallow junction can be easily formed in the extension region or the LDD region, and hence, the device characteristics can be easily improved. Specifically, in the ion implantation for forming the extension region 10 by using the gate electrode 5 and the insulating offset sidewall 6 as a mask, the increase of the acceleration energy can be minimized, and hence, a shallower junction can be easily formed in the extension region 10, so as to easily improve the device characteristics.

In this embodiment, after forming the insulating sidewall 7, a portion of the high dielectric constant gate insulating film 4C disposed away from the gate electrode 5 beyond the insulating sidewall 7 may be removed through, for example, the wet etching using hydrofluoric acid or the selective dry etching. In the case where the wet etching is employed, a notch may be formed in a side end portion of the high dielectric constant gate insulating film 4C by removing a part of the high dielectric constant gate insulating film 4C disposed below the insulating sidewall 7. Thus, the MISFET structure of the modification of Embodiment 3 shown in FIG. 15 can be easily realized.

Furthermore, in this embodiment, the degree of thinning the high dielectric constant gate insulating film 4C outside the gate electrode 5 is not particularly specified both below the insulating offset sidewall 6 and below the insulating sidewall 7. In the case where the high dielectric constant gate insulating film 4C is made of, for example, a HfSiON film, the high dielectric constant gate insulating film 4C is preferably thinned outside the gate electrode 5 to approximately 2 nm or less in order to suppress the increase of the gate/drain capacitance.

In this embodiment, the dielectric constant of the insulating offset sidewall 6 is preferably lower than that of the high dielectric constant gate insulating film 4C. Thus, the parasitic capacitance of the gate electrode 5 caused (mainly between the gate electrode 5 and the source/drain region 12) due to the insulating offset sidewall 6 can be reduced. Also, in this case, in the procedure for forming the insulating offset sidewall 6 shown in FIG. 22E, the insulating offset sidewall 6 is preferably formed, so as to attain a lower dielectric constant than the high dielectric constant gate insulating film 4C, by using the same material as that used for the high dielectric constant gate insulating film 4C with its composition ratios changed. Thus, the dielectric constant of the insulating offset sidewall 6 can be easily made lower than that of the high dielectric constant gate insulating film 4C while suppressing the lowering of the dielectric constant and the insulating property of the high dielectric constant gate insulating film 4C. Specifically, in the case where the high dielectric constant gate insulating film 4C is made of, for example, a HfSiON film, the Hf concentration in the HfSiON film used as the high dielectric constant gate insulating film 4C is set to approximately 50 at % and the Hf concentration in the insulating offset sidewall 6 made of a similar HfSiON film is set to approximately 30 at %. Thus, the dielectric constant of the insulating offset sidewall 6 can be made lower than that of the high dielectric constant gate insulating film 4C.

Furthermore, in this embodiment, the portion of the high dielectric constant gate insulating film 4C disposed outside the gate electrode 5 is thinned (first thinning) after forming the gate electrode 5 in the procedure of FIG. 22D and the portion of the high dielectric constant gate insulating film 4C disposed away from the gate electrode 5 beyond the insulating offset sidewall 6 is further thinned (second thinning) after forming the insulating offset sidewall 6 in the procedure of FIG. 22E. Instead, the first and second thinning may be omitted. Thus, the MISFET structure of Embodiment 3 shown in FIG. 11 can be easily realized. Alternatively, the first thinning alone can be omitted. Thus, the MISFET structure of the modification of Embodiment 3 shown in FIG. 12 can be easily realized. Alternatively, the second thinning alone can be omitted. Thus, the MISFET structure of the modification of Embodiment 3 shown in FIG. 13 can be easily realized. Also in the case where at least one thinning is omitted, the portion of the high dielectric constant gate insulating film 4C disposed away from the gate electrode 5 beyond the insulating sidewall 7 may be removed, for example, through the wet etching using hydrofluoric acid or the selective dry etching after forming the insulating sidewall 7. In the case where the wet etching is employed, a notch may be provided in a side end portion of the high dielectric constant gate insulating film 4C by removing a part of the high dielectric constant gate insulating film 4C below a side end portion of the insulating sidewall 7.

Also in this embodiment, the insulating sidewall 7 may or may not have a high dielectric constant. Furthermore, the insulating sidewall 7 may have a multilayered structure shown in, for example, FIG. 7A or 7B (see Embodiment 2) in this embodiment.

Furthermore, the gate electrode 5 is preferably a full silicide gate electrode or a metal gate electrode in this embodiment. Thus, the degree of integration, the performance and the operation speed of the semiconductor device can be definitely improved. For example, in the procedure for forming the gate electrode 5 shown in FIG. 22D, a protection film for covering the top face of the gate electrode 5 is formed, and the surface of the source/drain region 12 is silicided after forming the source/drain region 12 in the procedure of FIG. 22G. Then, after removing the protection film, the gate electrode 5 may be fully silicided. Thus, a semiconductor device having a full silicide gate electrode can be easily realized.

### Embodiment 8

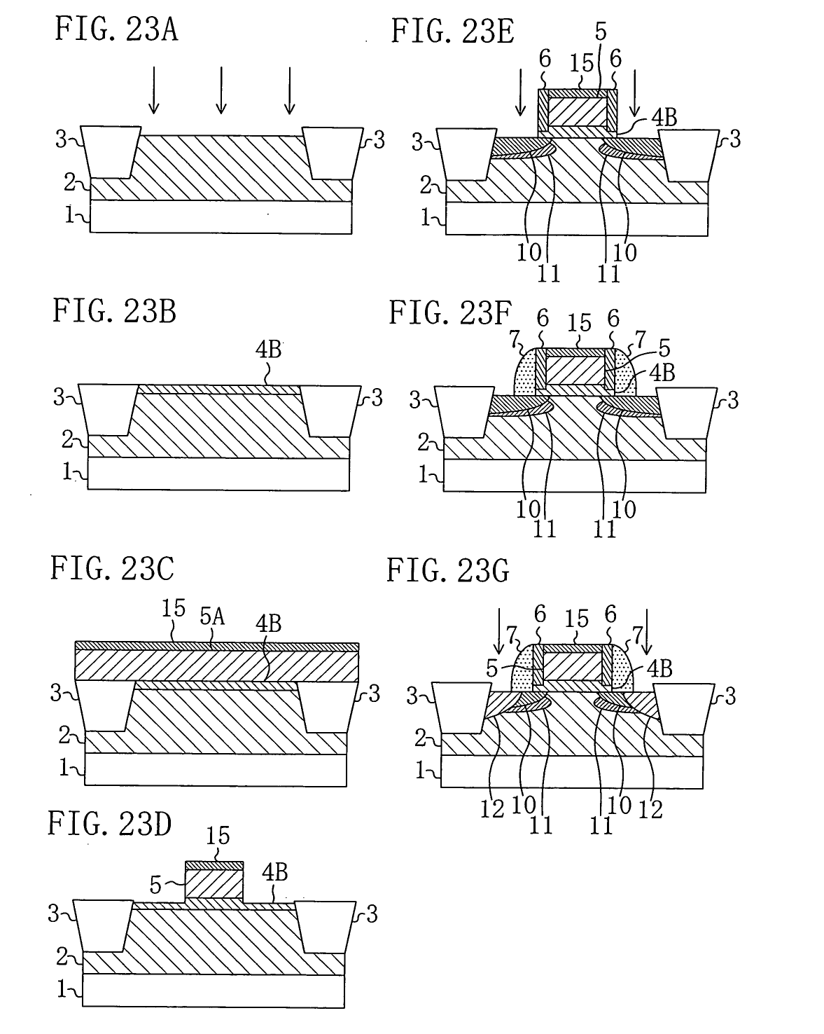

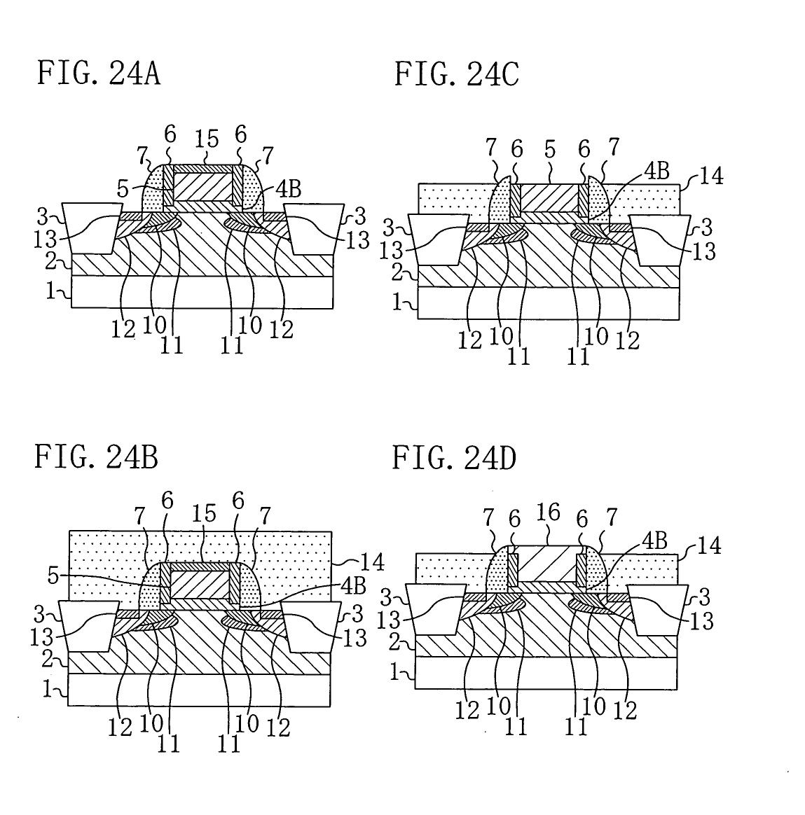

A method for fabricating a semiconductor device according to Embodiment 8 of the invention will now be described with reference to the accompanying drawings by exemplifying a fabrication method for an N-channel MISFET. FIGS. 23A through 23G and 24A through 24D are cross-sectional views for showing procedures in the method for fabricating a semiconductor device of Embodiment 8.

First, as shown in FIG. 23A, after an STI 3 corresponding to an isolation region is selectively formed on a substrate 1 of, for example, silicon, ions of, for example, B are implanted into the substrate 1 at implantation energy of 300 keV and a dose of 1×10¹³ cm⁻². Thus, a well 2 corresponding to an active region is formed. Subsequently, ion implantation for forming a punch through stopper (using ions of B at implantation energy of 150 keV and a dose of 1×10¹³ cm⁻²) and ion implantation for forming a channel (using ions of B at implantation energy of 20 keV and a dose of 5×10¹² cm⁻²) are performed.

Next, as shown in FIG. 23B, after a buffer insulating film made of, for example, a silicon oxide film (not shown) with a thickness of approximately 0.5 nm is formed on a portion of the well 2 surrounded with the STI 3, a high dielectric constant gate insulating film 4B made of, for example, a HfSiON film with a thickness of approximately 4 nm (corresponding to a thickness of approximately 1 nm when converted as an oxide film) is deposited.

Then, as shown in FIG. 23C, a gate electrode material film 5A made of, for example, a polysilicon film with a thickness of approximately 100 nm is formed on the high dielectric constant gate insulating film 4B, and thereafter, a cover film (protection film) 15 made of, for example, a silicon oxide film with a thickness of, for example, approximately 10 nm is deposited on the gate electrode material film 5A.

Next, after forming, on the cover film 15, a resist pattern (not shown) for covering a gate electrode forming region, the cover film 15 and the gate electrode material film 5A are successively etched by using the resist pattern as a mask, thereby forming a gate electrode 5 with a top face covered with the cover film 15 as shown in FIG. 23D. Thereafter, a portion of the high dielectric constant gate insulating film 4B disposed outside the gate electrode 5 is further removed by a thickness of approximately 2 nm through the selective etching. Thus, the portion of the high dielectric constant gate insulating film 4B disposed outside the gate electrode 5 can be thinned to a thickness of approximately 2 nm.

Subsequently, after depositing a high dielectric constant insulating film of, for example, a HfSiON film with a thickness of approximately 10 nm over the whole top surface of the substrate 1, the high dielectric constant insulating film is etched back, so as to form an insulating offset sidewall 6 on the side face of the gate electrode 5 as shown in FIG. 23E. Thereafter, a portion of the high dielectric constant gate insulating film 4B disposed away from the gate electrode 5 beyond the insulating offset sidewall 6 is removed through, for example, the wet etching using hydrofluoric acid or the selective dry etching. Subsequently, by using the gate electrode 5 and the insulating offset sidewall 6 as a mask, for example, As is ion implanted into the substrate 1 at implantation energy of 2 keV and a dose of 1×10¹⁵ cm⁻², thereby forming an extension region 10. Then, by using the gate electrode 5 and the insulating offset sidewall 6 as a mask, for example, B is ion implanted into the substrate 1 at implantation energy of 10 keV and a dose of 3×10¹³ cm⁻², thereby forming a pocket region 11. It is noted that the extension region 10 may be formed after forming the pocket region 11 in this embodiment.

Next, after depositing an insulating film of, for example, a SiN film with a thickness of approximately 50 nm over the whole surface of the substrate 1, the insulating film is etched back, so as to form an insulating sidewall 7 above the side face of the gate electrode 5 with the insulating offset sidewall 6 sandwiched therebetween as shown in FIG. 23F.

Then, by using the gate electrode 5, the insulating offset sidewall 6 and the insulating sidewall 7 as a mask, for example, As is ion implanted into the substrate 1 at implantation energy of 10 keV and a dose of 5×10¹⁵ cm⁻², and thereafter, the SPIKE RTA is performed at a temperature of, for example, 1050° C., thereby activating the implanted impurity. Thus, a source/drain region 12 is formed as shown in FIG. 23G.

Next, after a metal film of, for example, a Ni film with a thickness of approximately 10 nm is deposited over the whole surface of the substrate 1 including the source/drain region 12, RTA is performed so as to allow Ni included in the metal film to react with silicon included in the substrate 1 (specifically, a portion thereof where the source/drain region 12 is provided). Thus, a silicide layer 13 is formed on the source/drain region 12 as shown in FIG. 24A. Thereafter, an unreacted portion of the metal film remaining on the substrate 1 is peeled off to be removed.

Then, as shown in FIG. 24B, an interlayer insulating film 14 with a thickness of, for example, approximately 400 nm is deposited over the whole surface of the substrate 1 including the gate electrode 5.

Next, as shown in FIG. 24C, the interlayer insulating film 14 is polished by, for example, CMP (chemical mechanical polishing) until it has a top face at the same level as the cover film 15. Thereafter, the thus exposed cover film 15 is removed through the etching. At this point, an upper portion of the interlayer insulating film 14 obtained after the CMP and an upper portion of the insulating offset sidewall 6 are also removed.

Next, after depositing a metal film of, for example, a Ni film with a thickness of approximately 100 nm over the whole surface of the substrate 1 including the gate electrode 5, the RTA is performed so as to allow Ni included in the metal film to react with silicon included in the gate electrode 5. Thus, a full silicide gate electrode 16 is formed as shown in FIG. 24D.

In the fabrication method of this embodiment described above, the MISFET structure of Modification 2 of Embodiment 2 (shown in FIG. 9) employing an FUSI (full silicide) structure can be comparatively easily realized.

In this embodiment, after forming the insulating offset sidewall 6, a portion of the high dielectric constant gate insulating film 4B disposed away from the gate electrode 5 beyond the insulating offset sidewall 6 may be removed through, for example, the wet etching using hydrofluoric acid or the selective dry etching. In the case where the wet etching is employed, a notch may be formed in a side end portion of the high dielectric constant gate insulating film 4B by removing a part of the high dielectric constant gate insulating film 4B below a side end portion of the insulating offset sidewall 6. Thus, the MISFET structure of Modification 3 of Embodiment 2 (shown in FIG. 10) employing the FUSI structure can be easily realized.

Furthermore, in this embodiment, the degree of thinning the high dielectric constant gate insulating film 4B outside the gate electrode 5 is not particularly specified. In the case where the high dielectric constant gate insulating film 4B is made of, for example, a HfSiON film, the high dielectric constant gate insulating film 4B is preferably thinned outside the gate electrode 5 to approximately 2 nm or less (whereas so as not to expose the surface of the substrate 1) in order to suppress the increase of the gate/drain capacitance.

In this embodiment, the dielectric constant of the insulating offset sidewall 6 is preferably lower than that of the high dielectric constant gate insulating film 4B. Thus, the parasitic capacitance of the gate electrode 5 caused (mainly between the gate electrode 5 and the source/drain region 12) due to the insulating offset sidewall 6 can be reduced. Also, in this case, in the procedure for forming the insulating offset sidewall 6 shown in FIG. 23E, the insulating offset sidewall 6 is preferably formed, so as to attain a lower dielectric constant than the high dielectric constant gate insulating film 4B, by using the same material as that used for the high dielectric constant gate insulating film 4B with its composition ratios changed. Thus, the dielectric constant of the insulating offset sidewall 6 can be easily made lower than that of the high dielectric constant gate insulating film 4B while suppressing the lowering of the dielectric constant and the insulating property of the high dielectric constant gate insulating film 4B. Specifically, in the case where the high dielectric constant gate insulating film 4B is made of, for example, a HfSiON film, the Hf concentration in the HfSiON film used as the high dielectric constant gate insulating film 4B is set to approximately 50 at % and the Hf concentration in the insulating offset sidewall 6 made of a similar HfSiON film is set to approximately 30 at %. Thus, the dielectric constant of the insulating offset sidewall 6 can be made lower than that of the high dielectric constant gate insulating film 4B.

Furthermore, in this embodiment, the portion of the high dielectric constant gate insulating film 4B disposed away from the gate electrode 5 beyond the insulating offset sidewall 6 is removed after forming the insulating offset sidewall 6, and thereafter, the ion implantation for forming the extension region 10 and the pocket region 11 is performed. Instead, the ion implantation for forming the extension region 10 and the pocket region 11 may be performed with the thinned portion of the high dielectric constant gate insulating film 4B remaining in the portion away from the gate electrode 5 beyond the insulating offset sidewall 6 after forming the insulating offset sidewall 6. Even in this case, since the portion of the high dielectric constant gate insulating film 4B disposed outside the gate electrode 5 has a reduced thickness, the increase of the acceleration energy of the ion implantation can be suppressed. Therefore, a shallow junction can be easily formed in the extension region 10, so as to easily improve the device characteristics. Also in this case, after performing the ion implantation for forming the extension region 10 and the pocket region 11, the portion of the high dielectric constant gate insulating film 4B disposed away from the gate electrode 5 beyond the insulating offset sidewall 6 may be removed, so as to perform ion implantation for forming an extension region and a pocket region of another MISFET of a different channel or a different power system in the same substrate.

Also in this embodiment, the insulating sidewall 7 may or may not have a high dielectric constant. Furthermore, the insulating sidewall 7 may have a multilayered structure shown in, for example, FIG. 7A or 7B (see Embodiment 2) in this embodiment.

Furthermore, the gate electrode 5 is preferably a full silicide gate electrode or a metal gate electrode in this embodiment. Thus, the degree of integration, the performance and the operation speed of the semiconductor device can be definitely improved.

Although the FUSI structure is applied to the MISFET structure according to Modification 2 of Embodiment 2 in this embodiment, the FUSI structure may be applied to any of the MISFET structures of Embodiment 1 and its Modifications 1 through 3 (shown in FIGS. 1 and 3 through 5), Embodiment 2 and its Modifications 1 and 3 (shown in FIGS. 6, 8 and 10), Embodiment 3 and its modifications (shown in FIGS. 11 through 15) and Embodiment 4 (shown in FIGS. 16 through 19).

In each of Embodiments 1 through 8, the extension region 10 may be replaced with an LDD region.

In each of Embodiments 5 through 8, a P-channel MISFET may be formed instead of the N-channel MISFET.

In each of Embodiments 5 through 8, a buffer insulating film with a thickness of, for example, 0.2 nm may be formed between the gate electrode 5 and the high dielectric constant gate insulating film 4 (4A, 4B or 4C) for preventing degradation of the interface between the gate insulating film and the gate electrode.

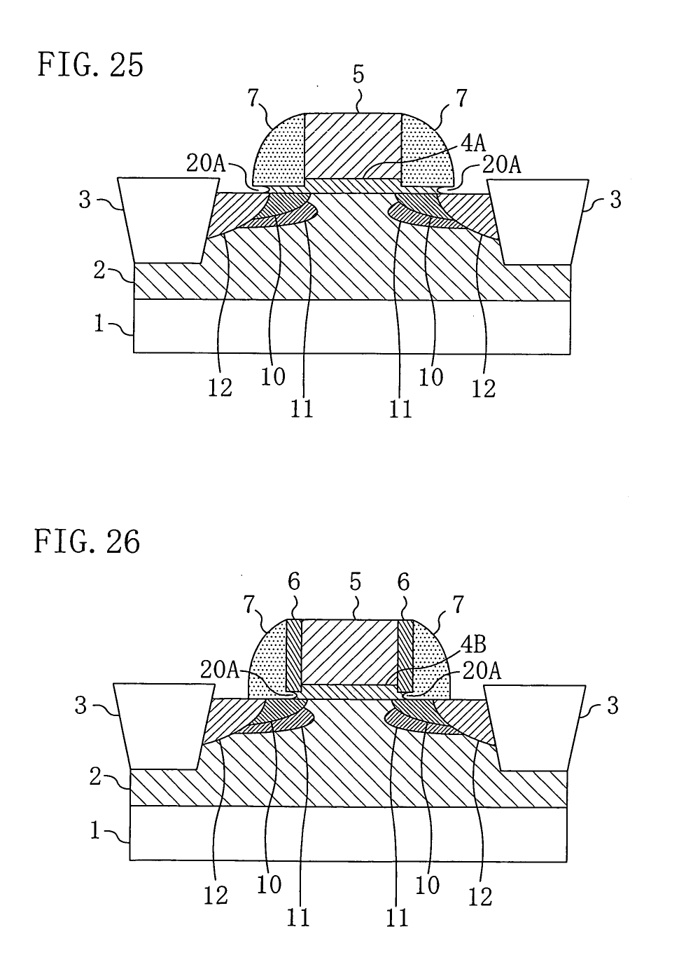

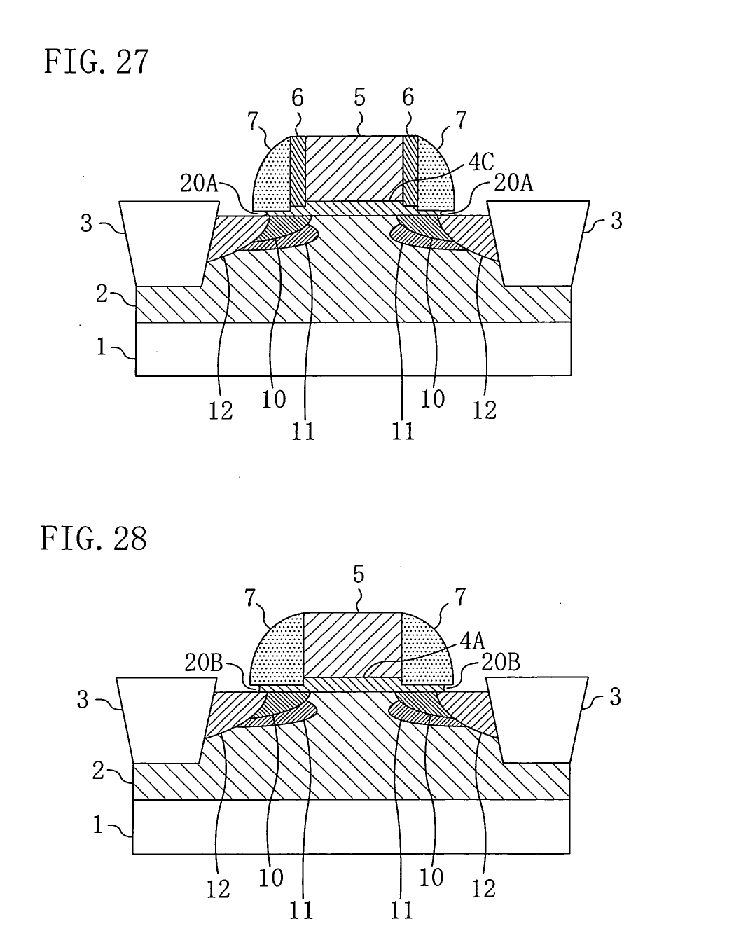

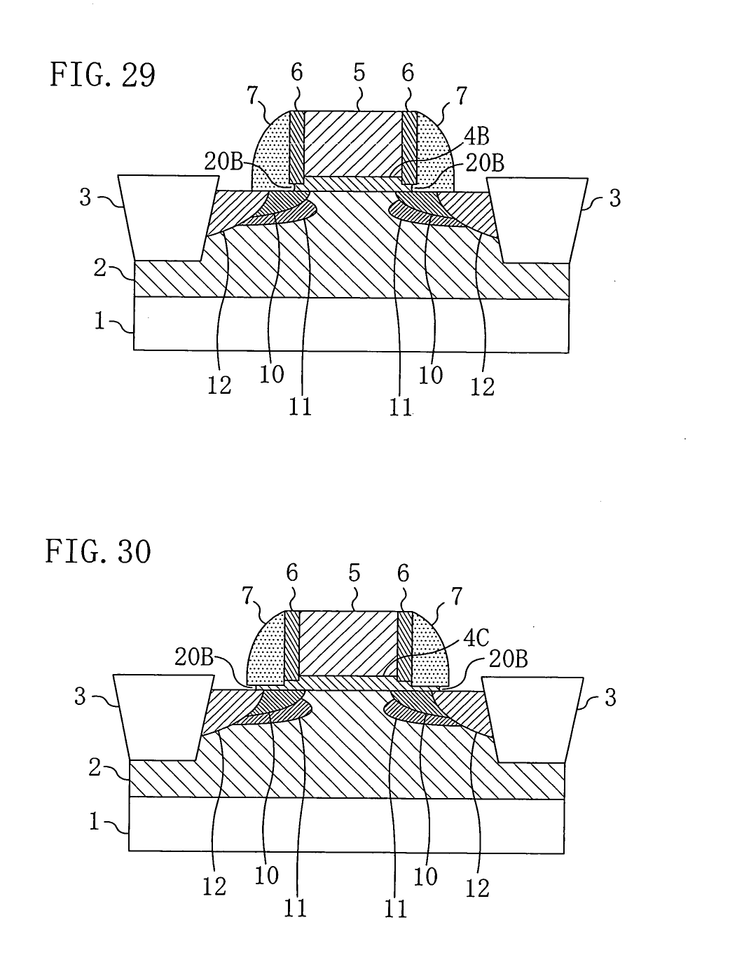

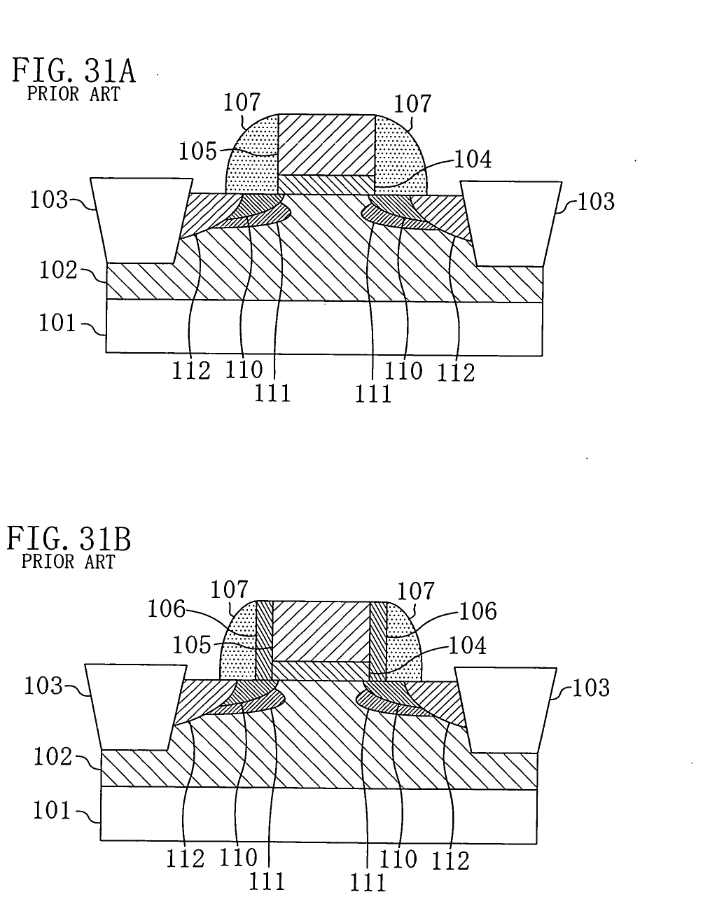

In each of Embodiments 1 through 8, in the case where a notch is provided in the side end portion of the high dielectric constant gate insulating film 4 (4A, 4B or 4C), the shape of the notch is not particularly specified as far as the capacitance between the gate electrode 5 and the source/drain region 12 can be reduced by forming the notch. For example, as shown in FIGS. 25 through 27, a notch 20A may be provided to reach a position away from the end of the insulating sidewall 7 or the end of the insulating offset sidewall 6. Alternatively, as shown in FIGS. 28 through 30, a notch 20B may be provided so as to allow the high dielectric constant gate insulating film 4 (4A, 4B or 4C) to have a side face vertical to the substrate surface after forming the notch. In FIGS. 25 and 28, the notches 20A and 20B are provided to the structure of Modification 2 of Embodiment 1 shown in FIG. 3; in FIGS. 26 and 29, the notches 20A and 20B are provided to the structure of Modification 2 of Embodiment 2 shown in FIG. 9; and in FIGS. 27 and 30, the notches 20A and 20B are provided to the structure of the modification of Embodiment 3 shown in FIG. 14.

What is claimed is:

1. A semiconductor device comprising:
a high dielectric constant gate insulating film formed on an active region of a substrate;
a gate electrode formed on said high dielectric constant gate insulating film; and
a high dielectric constant insulating sidewall formed on a side face of said gate electrode.

2. The semiconductor device of claim 1,
wherein said high dielectric constant gate insulating film continuously extends from under said gate electrode to under said high dielectric constant insulating sidewall.

3. The semiconductor device of claim 2,
wherein said high dielectric constant gate insulating film has a smaller thickness below said high dielectric constant insulating sidewall than below said gate electrode.

4. The semiconductor device of claim 1,
wherein said high dielectric constant insulating sidewall has a lower dielectric constant than said high dielectric constant gate insulating film.

5. The semiconductor device of claim 4,
wherein said high dielectric constant insulating sidewall is formed to have the lower dielectric constant than said high dielectric constant gate insulating film by using the same material as that used for said high dielectric constant gate insulating film with its composition ratios changed.

6. A semiconductor device comprising:
a high dielectric constant gate insulating film formed on an active region of a substrate;
a gate electrode formed on said high dielectric constant gate insulating film;
a first insulating sidewall formed on a side face of said gate electrode and having a high dielectric constant; and
a second insulating sidewall formed above the side face of said gate electrode with said first insulating sidewall sandwiched therebetween.

7. The semiconductor device of claim 6,
wherein said high dielectric constant gate insulating film continuously extends from under said gate electrode to under said first insulating sidewall.

8. The semiconductor device of claim 7,
wherein said high dielectric constant gate insulating film has a smaller thickness below said first insulating sidewall than below said gate electrode.

9. The semiconductor device of claim 6,
wherein said high dielectric constant gate insulating film continuously extends from under said gate electrode to under said second insulating sidewall.

10. The semiconductor device of claim 9,
wherein said high dielectric constant gate insulating film has an equivalent thickness below said first insulating sidewall and below said gate electrode, and
said high dielectric constant gate insulating film has a smaller thickness below said second insulating sidewall than below said gate electrode.

11. The semiconductor device of claim 9,
wherein said high dielectric constant gate insulating film has a smaller thickness below said first insulating sidewall than below said gate electrode, and
said high dielectric constant gate insulating film has an equivalent thickness below said second insulating sidewall and below said first insulating sidewall.

12. The semiconductor device of claim 9,
wherein said high dielectric constant gate insulating film has a smaller thickness below said first insulating sidewall than below said gate electrode, and
said high dielectric constant gate insulating film has a smaller thickness below said second insulating sidewall than below said first insulating sidewall.

13. The semiconductor device of claim 6,
wherein said first insulating sidewall has a lower dielectric constant than said high dielectric constant gate insulating film.

14. The semiconductor device of claim 13,
wherein said first insulating sidewall is formed to have the lower dielectric constant than said high dielectric constant gate insulating film by using the same material as that used for said high dielectric constant gate insulating film with its composition ratios changed.

15. The semiconductor device of claim 1,
wherein a notch is provided in a side end portion of said high dielectric constant gate insulating film.

16. The semiconductor device of claim 1,
wherein a buffer insulating film is provided between said substrate and said high dielectric constant gate insulating film.

17. The semiconductor device of claim 16,
wherein said buffer insulating film is made of a silicon oxide film or a silicon oxide nitride film.

18. The semiconductor device of claim 1,
wherein said gate electrode is a full silicide gate electrode or a metal gate electrode.

19. A method for fabricating a semiconductor device comprising the steps of:
(a) forming a high dielectric constant gate insulating film on an active region of a substrate;
(b) forming a gate electrode on said high dielectric constant gate insulating film; and
(c) forming a high dielectric constant insulating sidewall on a side face of said gate electrode.

20. The method for fabricating a semiconductor device of claim 19, further comprising, between the step (b) and the step (c), a step of thinning a portion of said high dielectric constant gate insulating film disposed outside said gate electrode.

21. The method for fabricating a semiconductor device of claim 19, further comprising, after the step (c), a step of removing a portion of said high dielectric constant gate insulating film disposed away from said gate electrode beyond said high dielectric constant insulating sidewall.

22. The method for fabricating a semiconductor device of claim 19,
wherein said high dielectric constant insulating sidewall has a lower dielectric constant than said high dielectric constant gate insulating film.

23. The method for fabricating a semiconductor device of claim 22,
wherein the step (c) includes a sub-step of forming said high dielectric constant insulating sidewall to have the lower dielectric constant than said high dielectric constant gate insulating film by using the same material as that used for said high dielectric constant gate insulating film with its composition ratios changed.

24. A method for fabricating a semiconductor device comprising the steps of:
(a) forming a high dielectric constant gate insulating film on an active region of a substrate;
(b) forming a gate electrode on said high dielectric constant gate insulating film;
(c) forming a first insulating sidewall having a high dielectric constant on a side face of said gate electrode; and
(d) forming a second insulating sidewall above the side face of said gate electrode with said first insulating sidewall sandwiched therebetween.

25. The method for fabricating a semiconductor device of claim 24, further comprising, between the step (b) and the step (c), a step of thinning a portion of said high dielectric constant gate insulating film disposed outside said gate electrode.

26. The method for fabricating a semiconductor device of claim 24, further comprising, between the step (c) and the step (d), a step of removing a portion of said high dielectric constant gate insulating film disposed away from said gate electrode beyond said first insulating sidewall.

27. The method for fabricating a semiconductor device of claim 24, further comprising steps of:
thinning a portion of said high dielectric constant gate insulating film disposed away from said gate electrode beyond said first insulating sidewall between the step (c) and the step (d); and
removing a portion of said high dielectric constant gate insulating film disposed away from said gate electrode beyond said second insulating sidewall after the step (d).

28. The method for fabricating a semiconductor device of claim 24,
wherein the step (b) includes a sub-step of forming a protection film for covering a top face of said gate electrode, and
the method further comprises, after the step (d), a step of siliciding a surface portion of said active region disposed away from said gate electrode beyond said second insulating sidewall, removing said protection film and full siliciding said gate electrode.

29. The method for fabricating a semiconductor device of claim 24,
wherein said first insulating sidewall has a lower dielectric constant than said high dielectric constant gate insulating film.

30. The method for fabricating a semiconductor device of claim 29,
wherein the step (c) includes a sub-step of forming said first insulating sidewall to have the lower dielectric constant than said high dielectric constant gate insulating film by using the same material as that used for said high dielectric constant gate insulating film with its composition ratios changed.

31. The method for fabricating a semiconductor device of claim 21,
wherein said high dielectric constant gate insulating film is selectively removed by wet etching.

32. The method for fabricating a semiconductor device of claim 19, further comprising, before the step (a), a step of forming a buffer insulating film on said active region,
wherein said high dielectric constant gate insulating film is formed above said active region with said buffer insulating film sandwiched therebetween in the step (a).
